(19) United States
(12) Patent Application Publication
(10) Pub. No.: US 2026/0198370 A1
(43) Pub. Date: Jul. 9, 2026

(54) ELECTRONIC DEVICE AND METHOD OF MANUFACTURING THE SAME

(71) Applicant: Advanced Semiconductor Engineering, Inc., Kaohsiung (TW)

(72) Inventors: Meng-Wei HSIEH, Kaohsiung (TW); Fan-Yu MIN, Kaohsiung (TW)

(73) Assignee: Advanced Semiconductor Engineering, Inc., Kaohsiung (TW)

(21) Appl. No.: 19/315,446

(22) Filed: Aug. 29, 2025

Related U.S. Application Data
(60) Provisional application No. 63/743,590, filed on Jan. 9, 2025.

(51) Int. Cl. H01L 23/31; H01L 21/56; H01L 23/00; H01L 23/498; H01L 25/18

(52) U.S. Cl. CPC H10W 74/124; H10W 70/69; H10W 74/01; H10W 90/701; H10W 74/15; H10W 90/00; H10W 90/724; H10W 90/734

(57) ABSTRACT

The present disclosure provides an electronic device. The electronic device includes a redistribution layer (RDL) having a first surface and a second surface opposite the first surface, an electronic component disposed over the first surface of the RDL, and a reinforcement layer disposed over the second surface of the RDL. A method for manufacturing an electronic device is also provided.

### CROSS REFERENCE TO RELATED APPLICATION

This application claims the benefit of U.S. provisional application No. 63/743,590, filed Jan. 9, 2025, the content of which is incorporated herein by reference in its entirety.

### BACKGROUND

### 1. Technical Field

The present disclosure relates to an electronic device and a method of manufacturing the electronic device.

### 2. Description of the Related Art

A Fan-out Multi-Chip Module (FO-MCM) integrates multiple chips within a single encapsulant, using a redistribution layer (RDL) to fan out I/Os. However, conventional FO-MCMs often lead to higher costs and lower yields, as damaged components cannot be removed or replaced once molding is complete.

### SUMMARY

In some arrangements, an electronic device includes a redistribution layer (RDL) having a first surface and a second surface opposite the first surface, an electronic component disposed over the first surface of the RDL, and a reinforcement layer disposed over the second surface of the RDL.

In some arrangements, an electronic device includes an RDL having a first surface and a second surface opposite the first surface, a first encapsulant disposed over the first surface of the RDL, a reinforcement structure disposed over the second surface of the RDL, and a second encapsulant disposed over the second surface of the RDL and adjacent to the reinforcement structure.

In some arrangements, a method for manufacturing an electronic device includes forming a reinforcement layer, forming an RDL over the reinforcement layer, forming an encapsulant over the RDL, and forming an opening in the encapsulant.

### BRIEF DESCRIPTION OF THE DRAWINGS

Aspects of some arrangements of the present disclosure are best understood from the following detailed description when read with the accompanying figures. It should be noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1B illustrates a cross-sectional view of an electronic device in accordance with some arrangements of the present disclosure.

FIG. 1C illustrates a cross-sectional view of an electronic device in accordance with some arrangements of the present disclosure.

FIG. 1D illustrates a cross-sectional view of an electronic device in accordance with some arrangements of the present disclosure.

FIG. 1E illustrates a cross-sectional view of an electronic device in accordance with some arrangements of the present disclosure.

FIG. 2 illustrates a cross-sectional view of an electronic device in accordance with some arrangements of the present disclosure.

FIG. 3 illustrates a cross-sectional view of an electronic device in accordance with some arrangements of the present disclosure.

FIG. 4A illustrates a top view of an electronic device in accordance with some arrangements of the present disclosure.

FIG. 4B illustrates a top view of an electronic device in accordance with some arrangements of the present disclosure.

FIG. 4C illustrates a top view of an electronic device in accordance with some arrangements of the present disclosure.

FIG. 4D illustrates a top view of an electronic device in accordance with some arrangements of the present disclosure.

FIG. 4E illustrates a top view of an electronic device in accordance with some arrangements of the present disclosure.

FIGS. 5A, 5B, 5C, 5D, 5E, 5F, 5G, 5H, and 5I are cross-sections of one or more stages of a method of manufacturing an electronic device in accordance with some arrangements of the present disclosure.

FIGS. 6A, 6B, 6C, 6D, 6E, 6F, 6G, 6H, and 6I are cross-sections of one or more stages of a method of manufacturing an electronic device in accordance with some arrangements of the present disclosure.

FIGS. 7A, 7B, 7C, 7D, 7E, 7F, 7G, and 7H are cross-sections of one or more stages of a method of manufacturing an electronic device in accordance with some arrangements of the present disclosure.

FIGS. 8A, 8B, 8C, 8D, 8E, 8F, 8G, 8H, 8I, 8J, 8K, and 8L are cross-sections of one or more stages of a method of manufacturing an electronic device in accordance with some arrangements of the present disclosure.

FIG. 9 illustrates a top view of a wafer in accordance with some arrangements of the present disclosure.

FIG. 10 illustrates a top view of a panel in accordance with some arrangements of the present disclosure.

### DETAILED DESCRIPTION

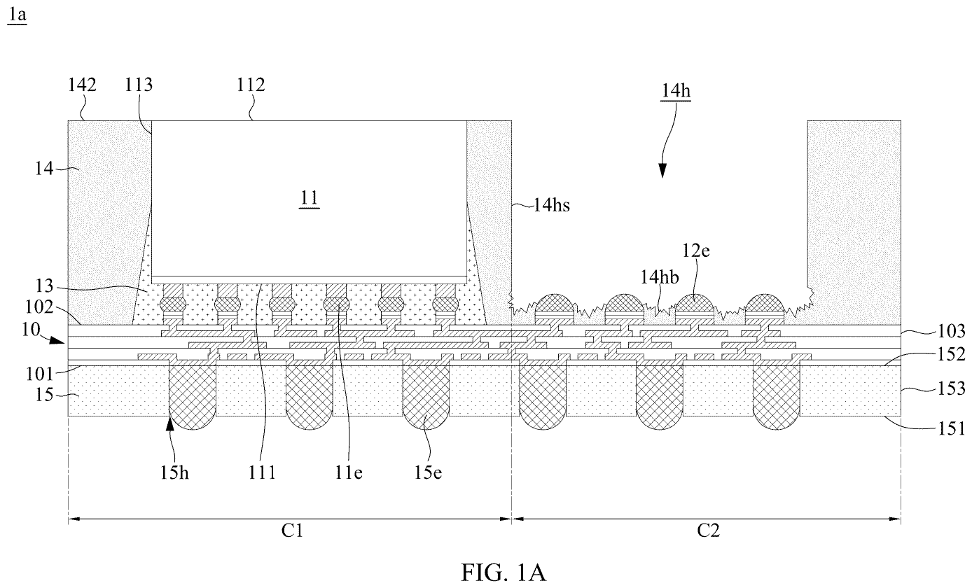

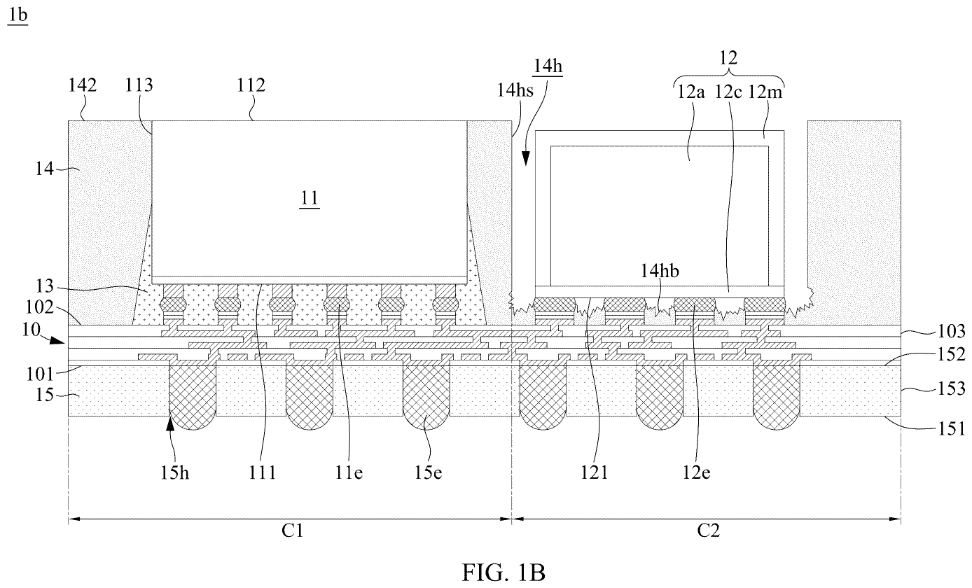

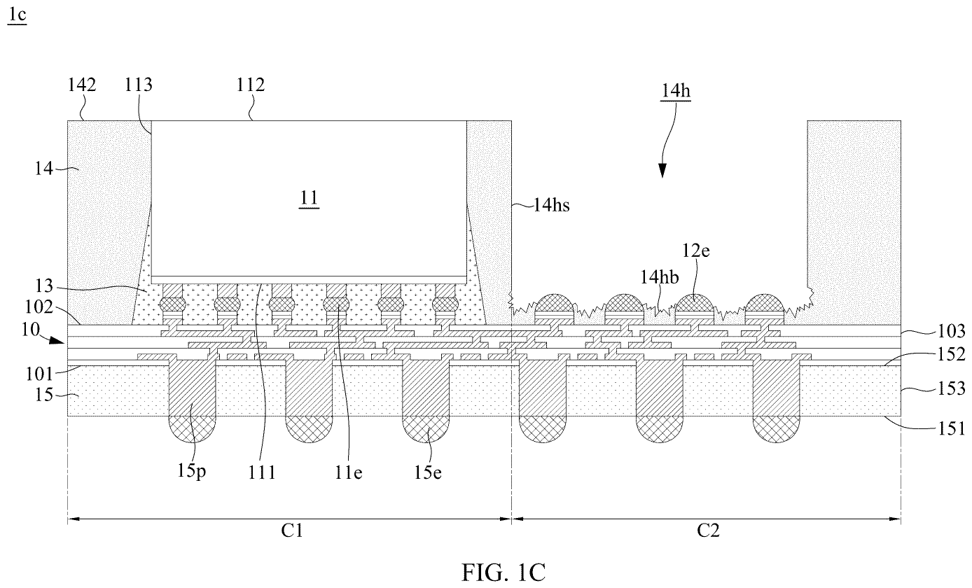

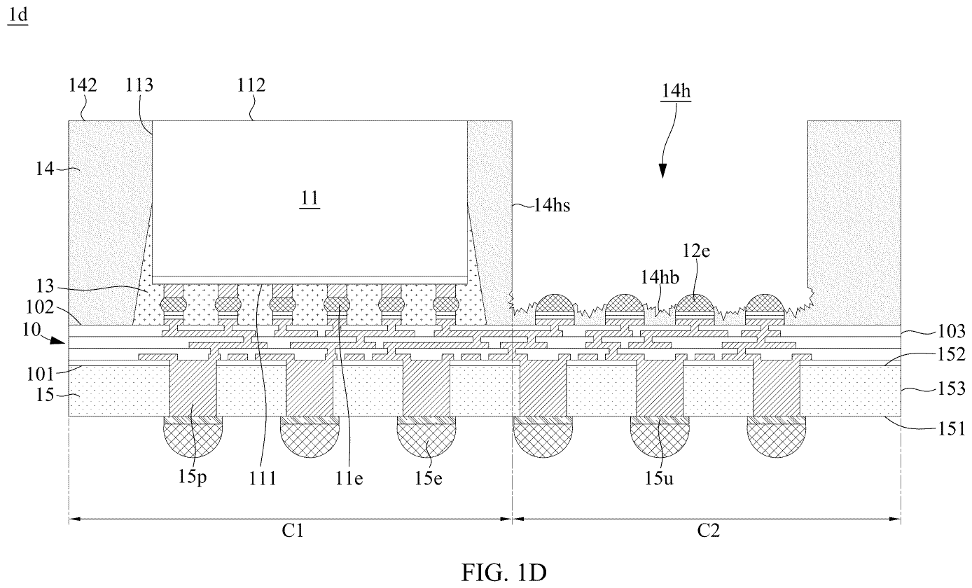

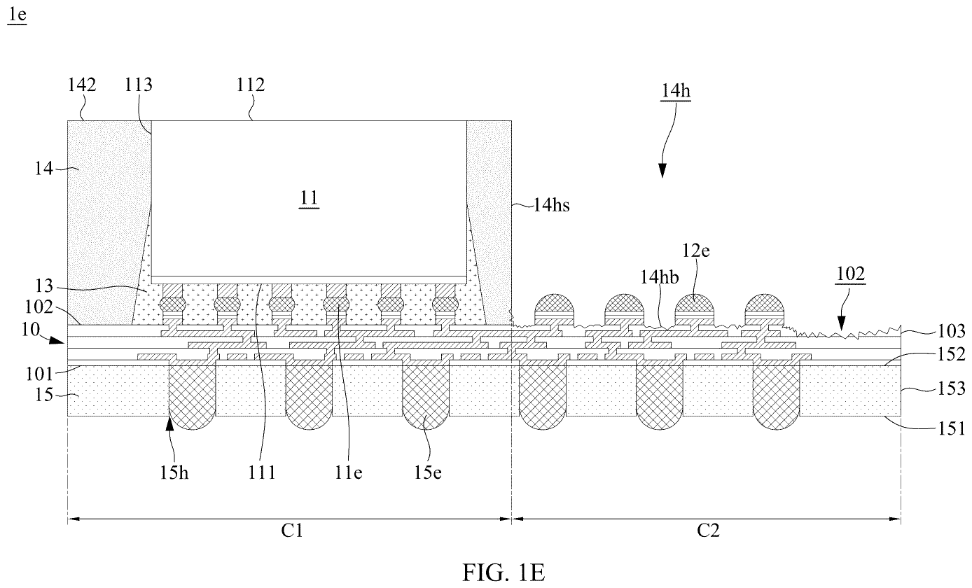

FIG. 1A illustrates a cross-sectional view of an electronic device 1a in accordance with some arrangements of the present disclosure. The electronic device 1a may include a package, such as an electronic device package. In some arrangements, the electronic device 1a may include a carrier 10, an electronic component 11, an underfill 13, an encapsulant 14, and a reinforcement layer 15.

The carrier 10 and the reinforcement layer 15 may be configured to provide structural support for the electronic component 11, the underfill 13, and the encapsulant 14. In some arrangements, the carrier 10 may be configured to provide a power connection for the electronic component 11. In some arrangements, the carrier 10 may be configured to reroute or redistribute the input/output (I/O) connections of the electronic component 11 to a different layout that is more suitable for packaging or interconnection with other components. For example, the carrier 10 may be configured to reroute or redistribute the I/O connections of the electronic component 11 to a board (not illustrated in the figures) through electrical contacts 15e.

The carrier 10 may include a surface 101, a surface 102 opposite the surface 101, and a surface 103 extending between the surface 101 and the surface 102. The surface 103 may be a lateral surface or a sidewall. The carrier 10 may include one or more redistribution layers (RDLs). For example, the carrier 10 may include one or more conductive layers and one or more dielectric layers. A portion of the conductive layer may be covered or encapsulated by the dielectric layer, while another portion of the conductive layer may be exposed from the dielectric layer to provide electrical connections. For example, the carrier 10 may include one or more conductive pads in proximity to, adjacent to, or embedded in and exposed by the surface 101 and/or the surface 102.

In some arrangements, the surface 102 of the carrier 10 may include a circuit portion C1 and a circuit portion C2. The circuit portions C1 and C2 represent conceptual or imaginary regions. The circuit portions C1 and C2 may be located adjacent to each other, sharing a common boundary, or they may be separated by one or more intermediate regions.

The circuit density of the circuit portion C1 may be different from that of the circuit portion C2. For example, the circuit density of the circuit portion C1 may be relatively higher than that of the circuit portion C2. For example, the circuit portion C1 may include a higher-density circuit and the circuit portion C2 may include a lower-density circuit. For example, the line spacing and/or the pad pitch of the circuit portion C1 may be relatively narrower than that of the circuit portion C2.

The conductive layer may include a conductive material such as a metal or metal alloy. Examples of the conductive materials include gold (Au), silver (Ag), copper (Cu), platinum (Pt), palladium (Pd), other metals or alloys, or a combination of two or more of these. The dielectric layer may include a dielectric material, such as an epoxy-based material (e.g., epoxy resin with silica/alumina fillers), a molding compound (e.g., an epoxy molding compound or another type of molding compound), Ajinomoto build-up film (ABF), polyimide (PI), benzocyclobutene (BCB), silicon oxide, silicon nitride, etc. In some arrangements, the dielectric layer may include other suitable non-conductive materials or insulating materials.

The electronic component 11 may be disposed over the surface 102 of the carrier 10. The electronic component 11 may be electrically connected to the carrier 10, and the electrical connections may be attained by way of solder bonding, Cu-to-Cu bonding, wire bonding, or hybrid bonding. For example, the electronic component 11 may be electrically connected with the circuit portion C1 through electrical contacts 11e. The electrical contacts 11e may be disposed over the conductive pads in the circuit portion C1.

The electronic component 11 may include a surface 111 facing the carrier 10, a surface 112 opposite to the surface 111, and a surface 113 extending between the surface 111 and the surface 112. The surface 111 may be an active surface, a front surface, or a front side. The surface 112 may be a backside surface or a backside. The surface 113 may be a lateral surface or a sidewall.

In some arrangements, the electronic component 11 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 11 may include a radio frequency integrated circuit (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. For example, the electronic component 11 may include a system on chip (SoC), a system-on-module (SoM), a system-in-package (SiP), or another type of IC that combines multiple components. Additionally, there may be any number of electronic components depending on design requirements.

In some arrangements, the electronic component 11 may include a computational array of multiple units that process values fetched from memory, and a hardware arbiter that synchronizes receipt of selected values by issuing a control signal to a control queue upon granting memory access.

The underfill 13 may be disposed between the carrier 10 and the electronic component 11. The underfill 13 may surround or cover the electrical contacts 11e. The underfill 13 may climb onto the surface 113 of the electronic component 11. The climbing height (or the vertical coverage height, or the extension length) of the underfill 13 may vary. For example, the climbing height of the underfill 13 on the left side of the electronic component 11 may be different from that on the right side.

The underfill 13 may be liquid at room temperature and may have a relatively low viscosity for easy flow and filling of spaces or voids. In some arrangements, the underfill 13 may include an epoxy-based underfill, a silicone-based underfill, or a polyimide-based underfill. The underfill 13 may be chosen based on functions such as reducing mechanical stress, improving thermal cycling performance, and protecting solder joints. For example, the underfill 13 may be designed to have a low modulus, low coefficient of thermal expansion (CTE), and to generate low stress during temperature cycling.

The encapsulant 14 may be disposed over the surface 102 of the carrier 10. The encapsulant 14 may cover the electronic component 11 and the underfill 13. The encapsulant 14 may have a surface (such as a top surface) 142. The surface 112 of the electronic component 11 and the surface 142 of the encapsulant 14 may be substantially coplanar or aligned.

The encapsulant 14 may define or have an opening 14h. The circuit portion C2 may be at least partially exposed from the opening 14h. The circuit portion C2 may vertically overlap the opening 14h. For example, the circuit portion C2 and the opening 14h of the encapsulant 14 may be overlapped in a direction substantially perpendicular to the surface 101 and/or the surface 102 of the carrier 10.

The opening 14h may not fully penetrate the encapsulant 14. For example, the carrier 10 may not be exposed from the opening 14h. The bottom 14hb of the opening 14h may be higher than the surface 102 of the carrier 10. The encapsulant 14 may form the bottom 14hb of the opening 14h.

For example, the encapsulant 14 may cover the surface 102 of the carrier 10 entirely, with the exception of the conductive pads located in the circuit portion C2. Specifically, the conductive pads in the circuit portion C2 may remain uncovered by the encapsulant 14, allowing electrical contacts 12e to be positioned directly over these conductive pads. The electrical contacts 12e may be surrounded by the encapsulant 14 but remain exposed through the opening 14h. This configuration enables the electrical contacts 12e to provide reliable electrical connections to another component, such as the package 12 illustrated in FIG. 1B.

In some arrangements, the electrical contacts 15e, 11e, and 12e may include solder balls or solder bumps, such as controlled collapse chip connection (C4) bumps, a ball grid array (BGA) or a land grid array (LGA). In some arrangements, the electrical contacts 15e, 11e, and 12e may reduce potential barriers at an interface between the carrier 10 and the other components.

The electrical contacts 12e may be on the bottom 14hb and surrounded by the sidewall 14hs of the opening 14h. In some arrangements, the sidewall 14hs may be inclined. The sidewall 14hs may be angled or oriented with respect to the surface 102 of the carrier 10. In some arrangements, the sidewall 14hs may be a vertical surface or a surface substantially vertical to the surface 102 of the carrier 10.

In some arrangements, the opening 14h may be configured to accommodate another component, such as the package 12 illustrated in FIG. 1B. In some arrangements, the opening 14h may be created using a laser-based process, and the laser technique may cause thermal effects on the adjacent surfaces, potentially affecting the material properties in those areas. For example, the sidewall 14hs and/or the bottom 14hb may become burnt or scorched as a result of the laser exposure. For example, the sidewall 14hs and/or the bottom 14hb may have a non-planar surface or topology. For example, instead of being flat or level, the surface of the sidewall 14hs and/or the bottom 14hb may be jagged or serrated. For example, the surface of the sidewall 14hs and/or the bottom 14hb may have varying elevations, contours, or other complex geometric features. In some arrangements, the encapsulant 14 may shield the carrier 10 from potential damage such as burning or scorching that may occur during the laser-based processing.

In some arrangements, the encapsulant 14 may include an epoxy resin with fillers, a molding compound (e.g., an epoxy molding compound or another type of molding compound), a polyimide, a phenolic compound or material, a material with a silicone dispersed therein, or a combination thereof. In some arrangements, the encapsulant 14 may include a material different from that of the underfill 13. In some arrangements, the flowability of the encapsulant 14 may be less than the flowability of the underfill 13.

The reinforcement layer 15 may be disposed over the surface 101 of the carrier 10. The reinforcement layer 15 may include a surface 151 facing away from the carrier 10, a surface 152 opposite to the surface 151, and a surface 153 extending between the surface 151 and the surface 152. The surface 153 may be a lateral surface or a sidewall.

The reinforcement layer 15 may vertically overlap the opening 14h of the encapsulant 14. For example, the reinforcement layer 15 and the opening 14h of the encapsulant 14 may be overlapped in a direction substantially perpendicular to the surface 101 and/or the surface 102 of the carrier 10. For example, the area of the carrier 10 that is not covered by the encapsulant 14 may be softer or less rigid compared to other regions of the carrier 10, making it more susceptible to mechanical failure or damage. The reinforcement layer 15 may be configured to enhance the overall mechanical strength and structural integrity of the carrier 10, thereby improving its durability and reliability during use.

In some arrangements, the reinforcement layer 15 may be sized to correspond precisely with the dimensions of the carrier 10. For example, the surface area of the reinforcement layer 15 may be substantially equal to the surface area of the carrier 10, ensuring comprehensive coverage and support and providing uniform reinforcement across the surface 101. For example, the footprint of the reinforcement layer 15 may be substantially equal to the footprint of the carrier 10.

Similarly, the width of the reinforcement layer 15 may be designed to match the width of the carrier 10. For example, the surface 153 of the reinforcement layer 15 may be substantially aligned or coplanar with the surface 103 of the carrier 10. This alignment contributes to the mechanical robustness of the carrier 10 without introducing unwanted irregularities or stress concentrations.

The reinforcement layer 15 may include one or more holes 15h. From the cross-sectional view, the holes 15h may penetrate completely through the reinforcement layer 15. For example, the holes 15h may extend between the surface 151 and the surface 152. The holes 15h may be configured to accommodate the electrical contacts 15e. For example, the conductive pads on the surface 101 of the carrier 10 may be at least partially exposed from the holes 15h. The electrical contacts 15e may each be disposed in a corresponding one of the holes 15h to establish an electrical connection with the conductive pads. For example, the electrical contacts 15e may be horizontally overlapped with the reinforcement layer 15. For example, the electrical contacts 15e may be overlapped with the reinforcement layer 15 in a direction substantially parallel to the surface 151 and/or the surface 152 of the reinforcement layer 15. For example, the electrical contacts 15e may extend between the surface 151 and the surface 152 of the reinforcement layer 15. For example, the electrical contacts 15e may provide a vertical electrical path between the surface 151 and the surface 152 of the reinforcement layer 15.

The reinforcement layer 15 may include a material that differs from that of the encapsulant 14 or the carrier 10. For example, the reinforcement layer 15 may include other suitable non-conductive or insulating materials to enhance electrical isolation while providing structural support. In some arrangements, the reinforcement layer 15 may possess a relatively high modulus, thereby improving its stiffness and resistance to deformation under mechanical stress. In some arrangements, the reinforcement layer 15 may possess a relatively low coefficient of thermal expansion (CTE) to minimize dimensional changes due to temperature fluctuations, thereby reducing thermal stresses.

For example, the reinforcement layer 15 may include glass (such as soda-lime glass or borosilicate glass), silicon (Si), silicon carbide (SiC), or other suitable materials. The Young's modulus of the glass may range from about 60 GPa to about 80 GPa. The Young's modulus of Si may range from about 130 GPa to about 188 GPa. The Young's modulus of SiC may range from about 100 GPa to about 500 GPa. The CTE of the glass may range from about 3 ppm/° C. to about 10 ppm/° C. The CTE of Si may range from about 2 ppm/° C. to about 4.5 ppm/° C. The CTE of SiC may range from about 2 ppm/° C. to about 5 ppm/° C.

In some arrangements, the reinforcement layer 15 may include a reinforcement skeleton, a brace (such as an inline-brace), or a guide rib. For example, the reinforcement layer 15 may include a framework to distribute loads more evenly throughout the structure. Additionally, the reinforcement layer 15 may contain various particles, fillers, or fibers that contribute to increased hardness, firmness, and overall durability.

FIG. 1B illustrates a cross-sectional view of an electronic device 1b in accordance with some arrangements of the present disclosure. The electronic device 1b is similar to the electronic device 1a in FIG. 1A, except that the electronic device 1b further includes the package 12.

The package 12 may be disposed over the surface 102 of the carrier 10. The package 12 may be disposed in the opening 14h. The package 12 may be surrounded by the encapsulant 14. The package 12 may be adjacent to the electronic component 11. The package 12 may be in the vicinity of the electronic component 11. In some arrangements, the distance (such as the shortest distance) between the package 12 and the electronic component 11 may be less than about 300 micrometers (μm). For example, the distance may be about 200 μm to 300 μm.

The package 12 may be electrically connected to the carrier 10, and the electrical connections may be attained by way of solder bonding, Cu-to-Cu bonding, wire bonding, or hybrid bonding. For example, the package 12 may be electrically connected with the circuit portion C2 through the electrical contacts 12e. In some arrangements, the electrical connection between the carrier 10 and the electronic component 11 may differ from that between the carrier 10 and the package 12. For example, the group of the electrical contacts 11e between the carrier 10 and the electronic component 11 may differ from the group of the electrical contacts 12e between the carrier 10 and the package 12. For example, the electronic component 11 may be connected through solder bonding, while the package 12 may be connected through hybrid bonding. Additionally, the package 12 may include a surface 121 facing the carrier 10. This surface 121 may be positioned higher than the surface 111 of the electronic component 11 relative to the surface 102 of the carrier 10.

The package 12 may include a memory package, such as a dynamic random access memory (DRAM) package, a static RAM (SRAM) package, a read-only memory (ROM) package, a flash memory package, a magnetoresistive RAM (MRAM) package, etc. However, the inventive concept is not limited thereto. For example, the package 12 may be or include other types of packages, such as a transceiver package, a processing package, a networking package, a voltage regulating package (which may provide a regulated voltage), etc.

In some arrangements, the package 12 may include a carrier 12c, a component 12a, and an encapsulant 12m. The carrier 12c may be configured to provide structural support for the component 12a and the encapsulant 12m. The component 12a may include one or more memory dies arranged in a vertical stack.

For example, FIG. 1B may illustrate only the outermost memory die, providing a focused view of its structure and layout without depicting the underlying or adjacent dies. In some arrangements, the component 12a may include other types of dies. The encapsulant 12m may be disposed over the carrier 12c and cover the component 12a. The encapsulant 12m may include a material as listed above with respect to the encapsulant 14. In some arrangements, the encapsulant 12m may include a material different from that of the encapsulant 14.

Conventionally, the package (such as the memory package) is molded together with the IC die within the encapsulant. During subsequent processing steps, the package is susceptible to damage that cannot be rectified by removing or replacing the package after the molding process. Consequently, this conventional approach introduces significant challenges and often results in higher manufacturing costs and lower production yields due to increased waste and rework caused by defective packages.

According to some arrangements of the present disclosure, the step of placing the package 12 is deferred by creating the opening 14h. For example, the opening 14h may be configured to serve as a predefined location or mounting point for the package 12. This arrangement allows the placement of the package 12 to be postponed until after the molding operation is complete. It also enables electrical testing of the RDL before die attachment, thereby facilitating early defect detection, reducing costs, and improving yield. Furthermore, the reinforcement layer 15 enhances the overall mechanical strength and structural integrity of the carrier 10, helping to reduce the risk of mechanical failure or damage during shipping.

FIG. 1C illustrates a cross-sectional view of an electronic device 1c in accordance with some arrangements of the present disclosure. The electronic device 1c is similar to the electronic device 1a in FIG. 1A, except that in the electronic device 1c, one or more interconnection structures 15p may be disposed in the holes 15h. The interconnection structure 15p may include a pillar, a pad, a via, a wire, or another conductive structure with a suitable shape.

The interconnection structures 15p may each be disposed in a corresponding one of the holes 15h to establish an electrical connection with the conductive pads. For example, the interconnection structures 15p may be horizontally overlapped with the reinforcement layer 15. For example, the interconnection structures 15p may be overlapped with the reinforcement layer 15 in a direction substantially parallel to the surface 151 and/or the surface 152 of the reinforcement layer 15. For example, the interconnection structures 15p may extend between the surface 151 and the surface 152 of the reinforcement layer 15. For example, the interconnection structures 15p may provide a vertical electrical path between the surface 151 and the surface 152 of the reinforcement layer 15.

The electrical contacts 15e may each be disposed over a corresponding one of the interconnection structures 15p. The interconnection structures 15p and the electrical contacts 15e may collectively provide an external connection interface for the electronic device 1c. In some arrangements, the interconnection structures 15p may include copper (Cu), which offers both excellent electrical conductivity and mechanical strength. Meanwhile, the electrical contacts 15e may be formed from solder material, which serves to establish a reliable electrical connection as well as a robust mechanical bond between the device and its external circuitry.

FIG. 1D illustrates a cross-sectional view of an electronic device 1d in accordance with some arrangements of the present disclosure. The electronic device 1d is similar to the electronic device 1c in FIG. 1C, except that the electronic device 1d further includes a metal layer 15u.

The metal layer 15u may be disposed between the interconnection structure 15p and the electrical contact 15e. The metal layer 15u may include an under-bump metallization (UBM) layer. The metal layers 15u may each be disposed over a corresponding one of the interconnection structures 15p.

The metal layer 15u may include a monolithic layer or a multilayer stack, serving as an intermediate interface that enhances adhesion, prevents intermetallic compound formation, and improves solder wettability. The metal layer 15u may include nickel (Ni), chromium (Cr), palladium (Pd), titanium (Ti), copper (Cu), gold (Au), nickel-phosphorus (Ni—P), or nickel-vanadium (Ni—V), titanium tungsten (TiW), or other metals or alloys.

FIG. 1E illustrates a cross-sectional view of an electronic device 1e in accordance with some arrangements of the present disclosure. The electronic device 1e is similar to the electronic device 1a in FIG. 1A, except that a portion of the carrier 10 may be covered by the encapsulant 14, while another portion of the carrier 10 may be exposed. For example, approximately half of the carrier 10 may be encapsulated by the encapsulant 14, with the remaining half left uncovered. For example, the circuit portion C1 may be covered by the encapsulant 14, while the circuit portion C2 may be exposed.

The carrier 10 may be damaged during the laser-based processing used to create the exposed portion. For example, a portion of the surface 102 of the carrier 10 adjacent to the electrical contacts 12e may be jagged or serrated. For example, the surface 102 of the carrier 10 may have varying elevations, contours, or other complex geometric features.

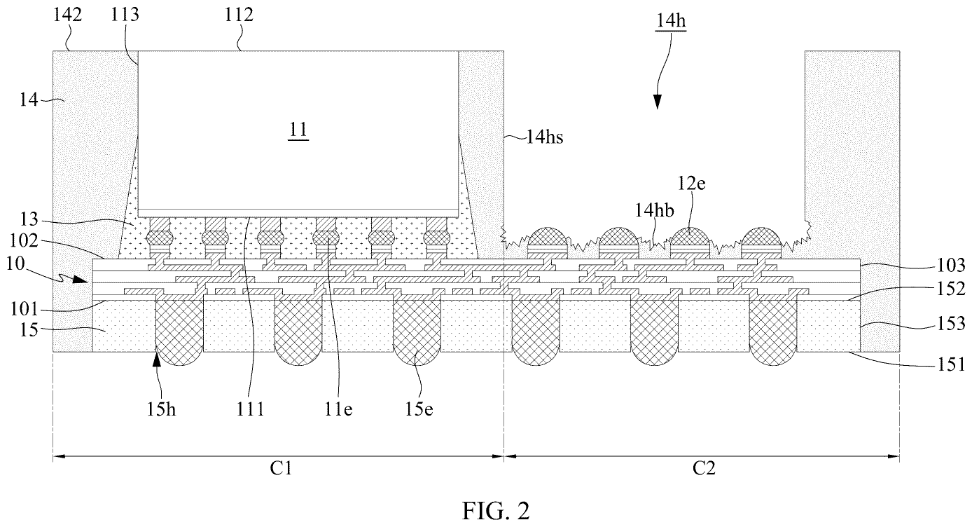

FIG. 2 illustrates a cross-sectional view of an electronic device 2 in accordance with some arrangements of the present disclosure. The electronic device 2 is similar to the electronic device 1a in FIG. 1A, except that the surface 153 of the reinforcement layer 15 and the surface 103 of the carrier 10 may both be covered by the encapsulant 14. The encapsulant 14 helps to prevent environmental damage, such as moisture ingress or mechanical wear, thereby extending the lifespan and reliability of the reinforcement layer 15 and the carrier 10.

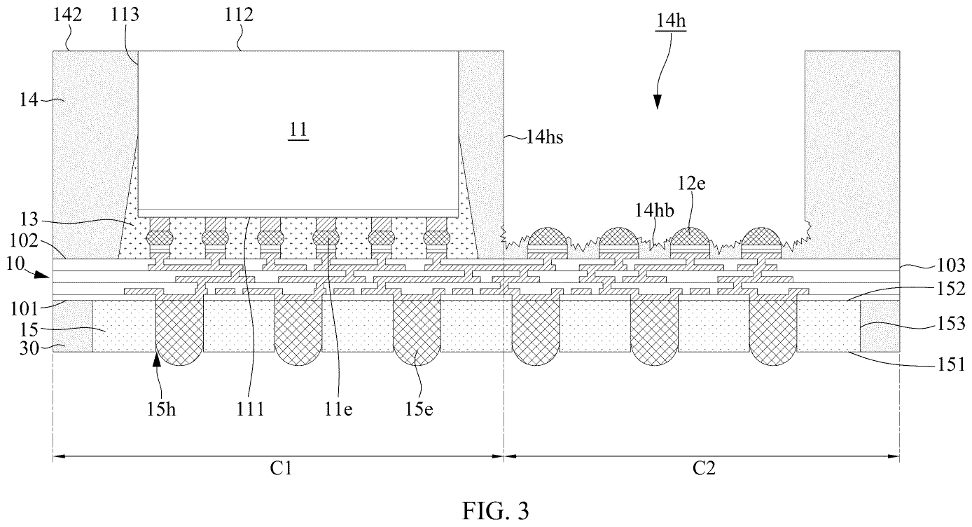

FIG. 3 illustrates a cross-sectional view of an electronic device 3 in accordance with some arrangements of the present disclosure. The electronic device 3 is similar to the electronic device 1a in FIG. 1A, except that the surface 153 of the reinforcement layer 15 may be misaligned with or non-coplanar to the surface 103 of the carrier 10. The electronic device 3 further includes an encapsulant 30. The encapsulant 30 may include a material as listed above with respect to the encapsulant 14. In some arrangements, the encapsulant 30 and the encapsulant 14 may include the same material. In some arrangements, the encapsulant 30 may include a material different from that of the encapsulant 14.

The encapsulant 30 may be adjacent to the reinforcement layer 15. The encapsulant 30 may be horizontally overlapped with the reinforcement layer 15. For example, the encapsulant 30 may be overlapped with the reinforcement layer 15 in a direction substantially parallel to the surface 151 and/or the surface 152 of the reinforcement layer 15. The encapsulant 30 may be disposed over the surface 153 of the reinforcement layer 15.

In some arrangements, the encapsulant 30 may be applied to at least the opposite sides of the reinforcement layer 15. For example, the encapsulant 30 may fully surround the reinforcement layer 15, providing comprehensive coverage. Together, the reinforcement layer 15 and the encapsulant 30 may form a composite reinforcement structure composed of two different materials, each contributing distinct mechanical or protective properties to enhance the overall performance and durability of the electronic device 3.

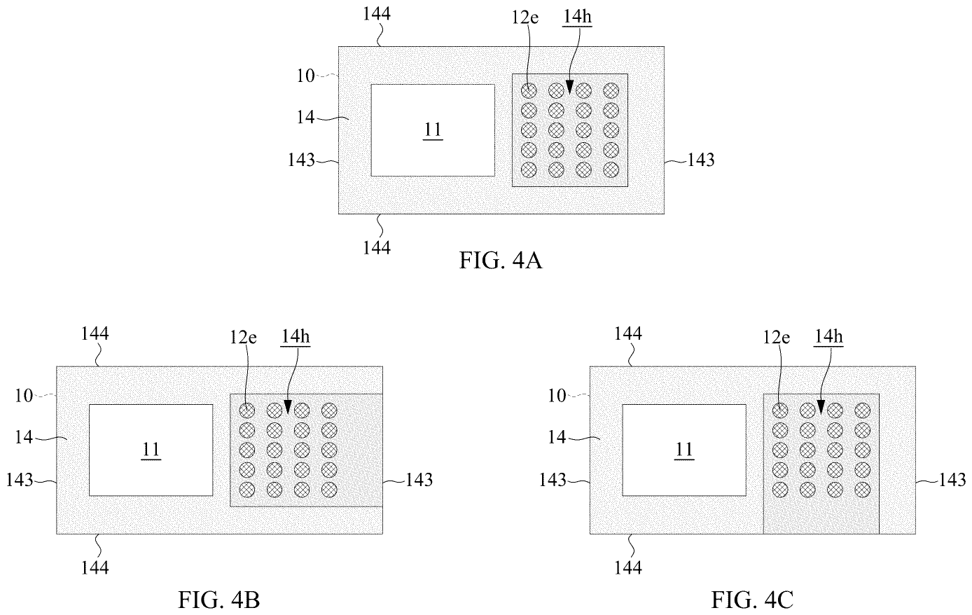

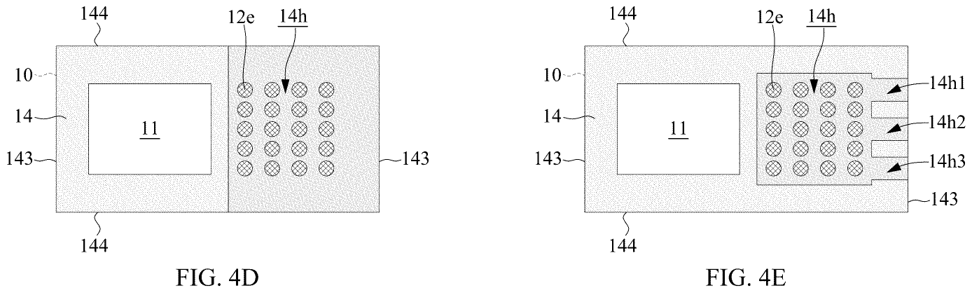

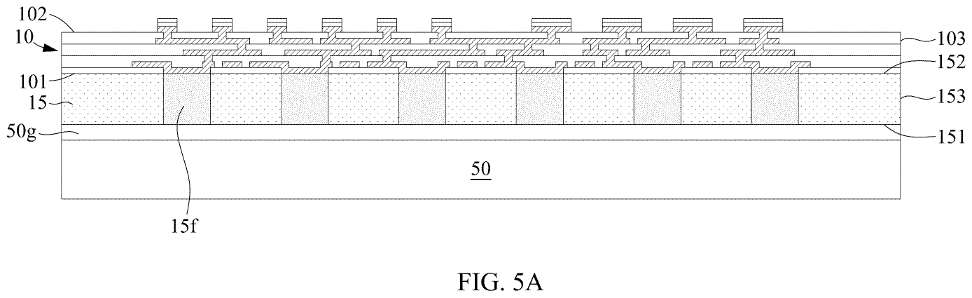

FIGS. 4A, 4B, 4C, 4D, and 4E illustrate top views of electronic devices in accordance with some arrangements of the present disclosure. Although the opening 14h may not fully penetrate the encapsulant 14 and the carrier 10 may be covered by the encapsulant 14, the disclosure is not limited thereto. For example, the carrier 10 may be exposed from the opening 14h.

Referring to FIG. 4A, the encapsulant 14 may include sides 143 and sides 144. The sides 143 may be parallel to each other and substantially perpendicular to the sides 144. The sides 144 may be parallel to each other and substantially perpendicular to the sides 143. The sides 143 may be shorter sides and the sides 144 may be longer sides. The opening 14h may have four sides from the top view. The encapsulant 14 may form an enclosure wall defining the opening 14h.

In an assembled state (such as in some arrangements with the package 12), the enclosure wall can enhance the structural integrity and protection of the package 12 by providing coverage on multiple sides. In some arrangements, the electronic devices 1a, 1c, 1d, 2, and 3 may be illustrated in a top view in FIG. 4A.

Referring to FIG. 4B, the opening 14h may not be fully enclosed or surrounded. The opening 14h may be open to the exterior through the side 143 of the encapsulant 14. The side 143 of the encapsulant 14 may allow the opening 14h to be open to the outside. The opening 14h may be exposed to an external environment through the side 143 of the encapsulant 14.

When the package 12 is disposed in the opening 14h, the package 12 may protrude beyond the encapsulant 14 through the side 143 of the encapsulant 14. The size of the package 12 is not necessarily constrained by the dimensions of the encapsulant 14. This flexibility allows for greater design versatility and optimization of both components to meet specific functional and spatial requirements.

The three-dimensional form factors of the protruding section of the package 12 can be strategically chosen. In some arrangements, the protruding section of the package 12 can enhance thermal management by providing an increased surface area for heat dissipation. In some arrangements, the electronic device 1e may be illustrated in a top view in FIG. 4B.

Referring to FIG. 4C, the opening 14h may not be fully enclosed or surrounded. The opening 14h may be open to the exterior through the side 144 of the encapsulant 14. The side 144 of the encapsulant 14 may allow the opening 14h to be open to the outside. The opening 14h may be exposed to an external environment through the side 144 of the encapsulant 14.

When the package 12 is disposed in the opening 14h, the package 12 may protrude beyond the encapsulant 14 through the side 144 of the encapsulant 14. The size of the package 12 is not necessarily constrained by the dimensions of the encapsulant 14. This flexibility allows for greater design versatility and optimization of both components to meet specific functional and spatial requirements. In some arrangements, the electronic devices 1a, 1c, 1d, 2, and 3 may be illustrated in a top view in FIG. 4C.

Referring to FIG. 4D, approximately half of the carrier 10 may be encapsulated by the encapsulant 14, with the remaining half left uncovered. In some arrangements, the electronic device 1e may be illustrated in a top view in FIG. 4D.

Referring to FIG. 4E, the opening 14h may have four sides from the top view. The encapsulant 14 may form an enclosure wall defining the opening 14h. The encapsulant 14 may define sub-openings 14h1, 14h2, and 14h3 on the side 143. The sub-openings 14h1, 14h2, and 14h3 may be arranged sequentially along the side 143. The sub-openings 14h1, 14h2, and 14h3 may each be smaller than the opening 14h. The opening 14h may be open to the exterior through the sub-openings 14h1, 14h2, and 14h3. The sub-openings 14h1, 14h2, and 14h3 may allow the opening 14h to be open to the outside. The opening 14h may be exposed to an external environment through the sub-openings 14h1, 14h2, and 14h3 of the encapsulant 14.

In some arrangements, the sub-openings 14h1, 14h2, and 14h3 may allow flux or chemical agents to flow out of the opening 14h during a cleaning operation. In some arrangements, the sub-openings 14h1, 14h2, and 14h3 may facilitate interaction between interior and exterior spaces, enhancing ventilation, fluid flow, or other design functions. The sub-openings 14h1, 14h2, and 14h3 may function as communication slots.

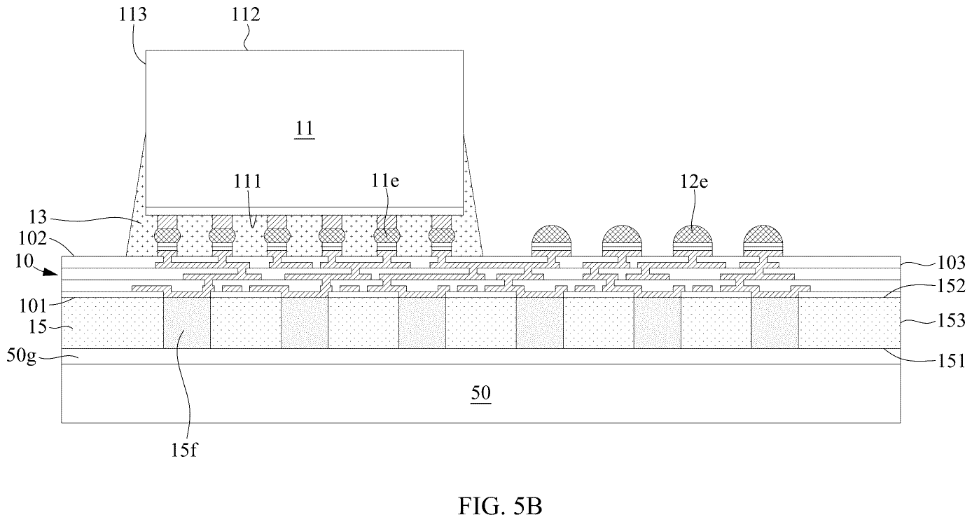

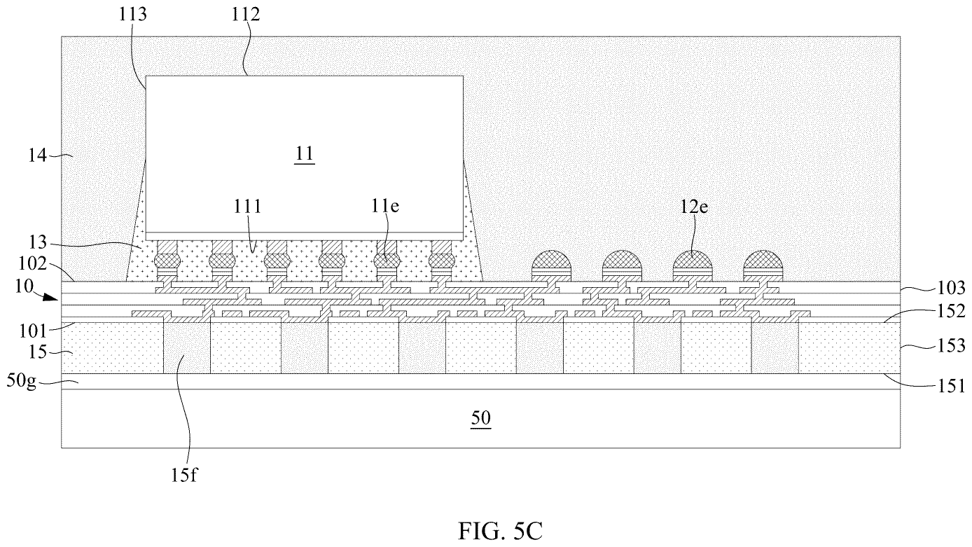

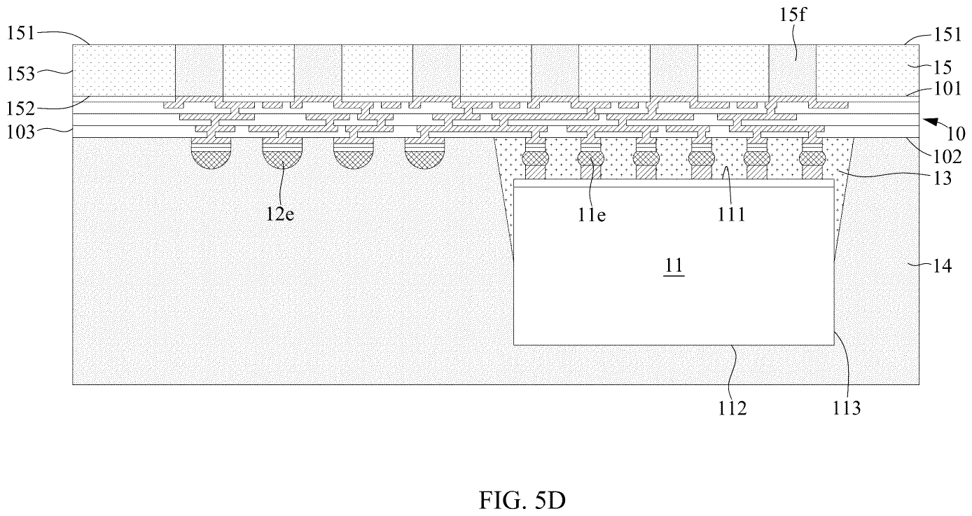

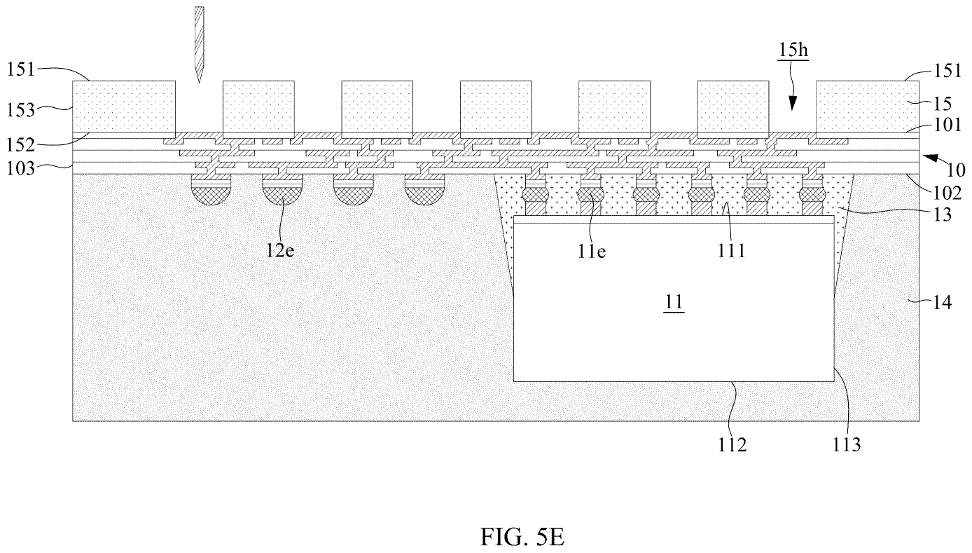

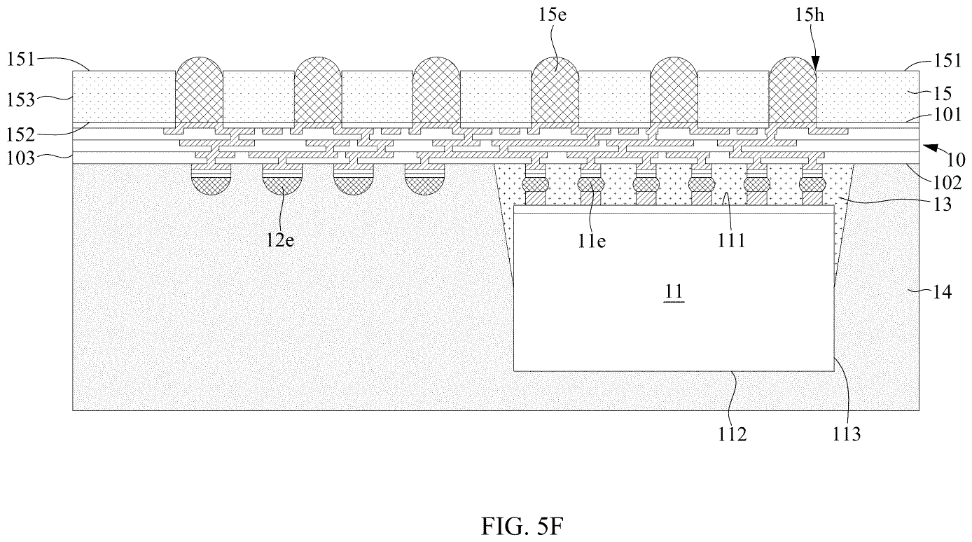

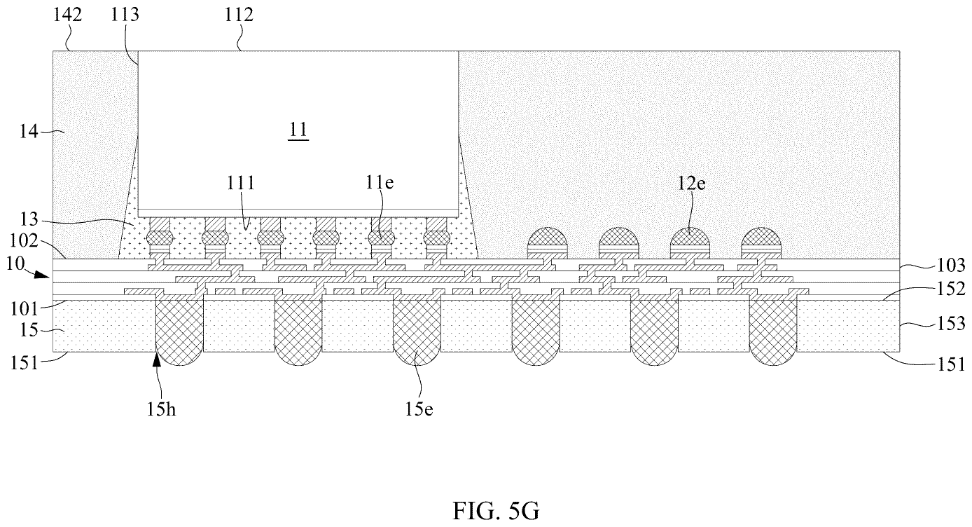

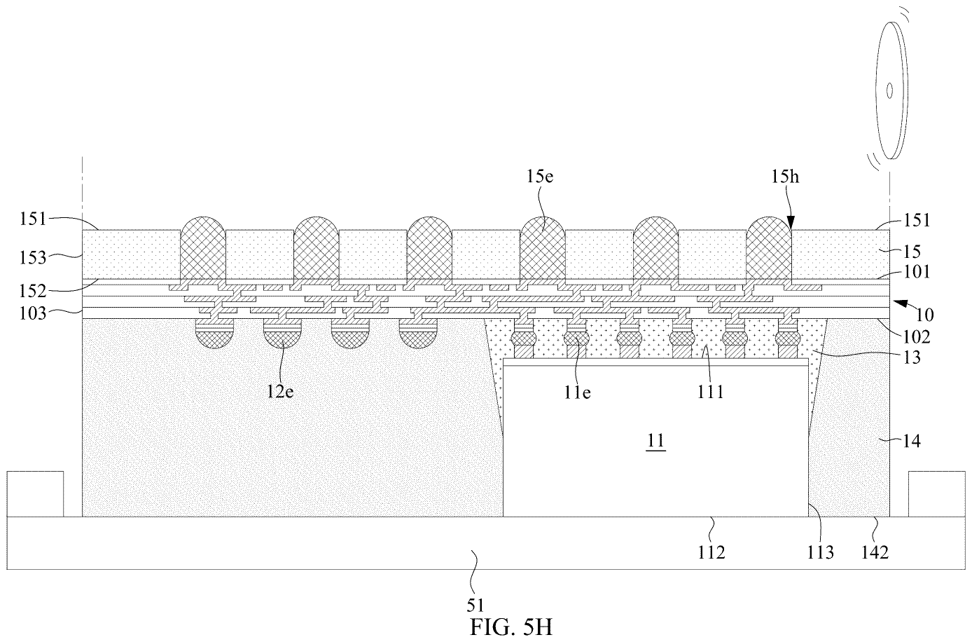

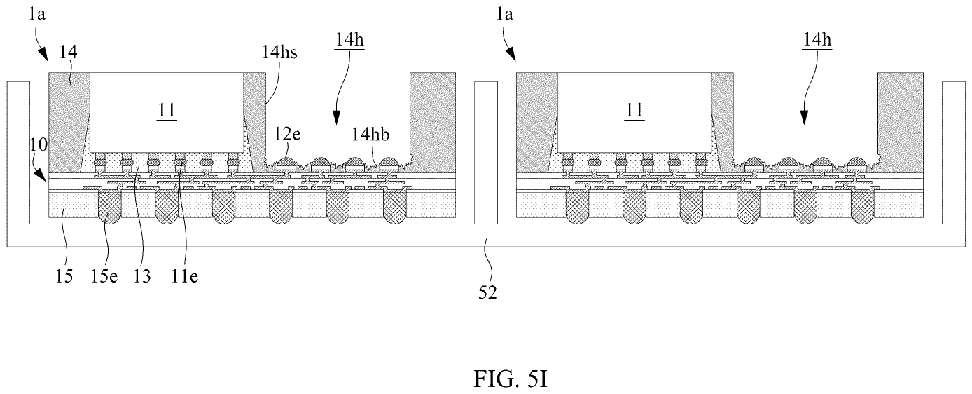

FIGS. 5A, 5B, 5C, 5D, 5E, 5F, 5G, 5H, and 5I are cross-sections of one or more stages of a method of manufacturing an electronic device in accordance with some arrangements of the present disclosure. At least some of these figures have been simplified to better understand the aspects of the present disclosure. In some arrangements, the electronic device 1a may be manufactured through the steps illustrated in FIGS. 5A, 5B, 5C, 5D, 5E, 5F, 5G, 5H, and 5I.

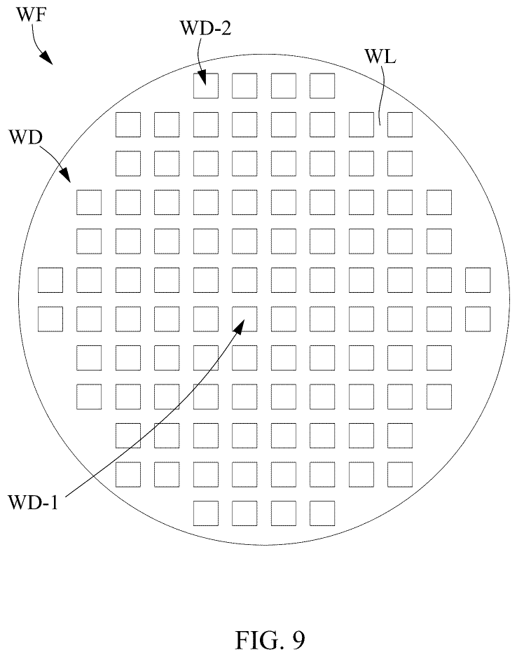

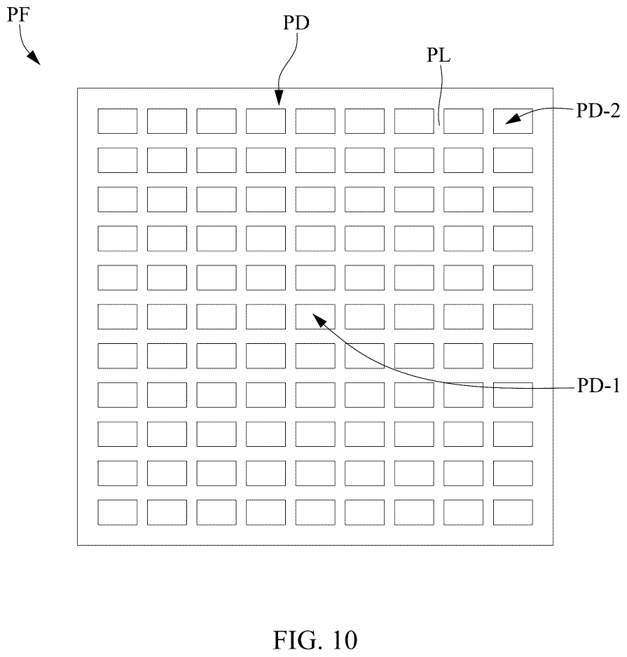

Referring to FIG. 5A, a temporary carrier 50 may be provided (e.g., manufactured or obtained). The temporary carrier 50 may be a glass carrier, a metal carrier, a ceramic carrier, or other suitable carriers. The temporary carrier 50 may include a wafer (such has the wafer WF in FIG. 9). The temporary carrier 50 may include a panel (such has the panel PF in FIG. 10), and the size thereof can be approximately 300 mm square, 500 mm square, 600 mm square, or larger. For example, the electronic device 1a may be implemented using a panel level packaging (PLP) process.

The reinforcement layer 15 may be formed over the temporary carrier 50. The reinforcement layer 15 may be attached to the temporary carrier 50 through an adhesive layer 50g. The adhesive layer 50g may include a die attach film (DAF), a glue, a bonding layer, an underfill, or another suitable material. The reinforcement layer 15 may include a filling material 15f disposed in the locations predefined to form one or more holes. The filling material 15f may be different from the material of the reinforcement layer 15, and can be removed in FIG. 5E.

The carrier 10 may be formed over the reinforcement layer 15. For example, one or more redistribution layers (RDLs) can be fabricated over the reinforcement layer 15 by employing various semiconductor manufacturing processes such as spinning, photolithography, etching, sputtering, electroplating, and other related techniques.

Referring to FIG. 5B, the electronic component 11 may be disposed over the carrier 10. The underfill 13 may be disposed over the carrier 10. The underfill 13 may connect the electronic component 11 to the carrier 10. In some arrangements, more than two electronic components may be placed on the carrier 10 in a batch and subjected to similar or identical processes in the manufacturing method. For example, the electronic components 11 may be arranged in an N×M array.

Referring to FIG. 5C, the encapsulant 14 may be disposed over the carrier 10 to cover the electronic component 11 and the underfill 13. In some arrangements, the encapsulant 14 may be formed by a molding technique, such as transfer molding, injection molding, or compression molding.

Referring to FIG. 5D, the temporary carrier 50 and the adhesive layer 50g may be removed, and the surface 151 of the reinforcement layer 15 may be exposed.

Referring to FIG. 5E, the filling material 15f may be removed. One or more holes 15h may be formed in the reinforcement layer 15 by a laser direct ablation (LDA) process, a laser drilling process, a laser cutting process, or an etching process.

Referring to FIG. 5F, the electrical contact 15e may be formed in the holes 15h.

Referring to FIG. 5G, a planarization operation or a grinding operation may be performed to remove a portion of the encapsulant 14 to expose the surface 112 of the electronic component 11. The planarization operation or grinding operation may include an abrasive machining process that uses a grinding wheel or grinder, a chemical mechanical planarization (CMP) process, an etching process, or a laser direct ablation (LDA) process.

Referring to FIG. 5H, the structure obtained from the operation of FIG. 5G may be disposed over a dicing tape 51. A singulation operation may be performed. The electronic device assembly may be singulated or separated into a plurality of individual units in a singulation operation. In some arrangements, the singulation operation may be applied using a saw blade or laser cutting tool.

Referring to FIG. 5I, the individual units obtained from the operation of FIG. 5H may be disposed or sorted over a board 52. For example, the board 52 may include a plurality of holes or openings, and the individual units may be disposed in a corresponding opening. The opening 14h may be formed by a laser direct ablation (LDA) process, a laser drilling process, a laser cutting process, or an etching process.

In some arrangements, the product may be shipped to a different production line for the placement of the package 12. In some arrangements, an electrical test can be performed on the carrier 10 before mounting the package 12.

In some arrangements, an electrical test may be conducted after the package 12 has been placed within the opening 14h. If either the package 12 or the carrier 10 is found to be defective during this test, the method includes removing the package 12 from the opening 14h without destroying the encapsulant 14 to allow for replacement or further inspection.

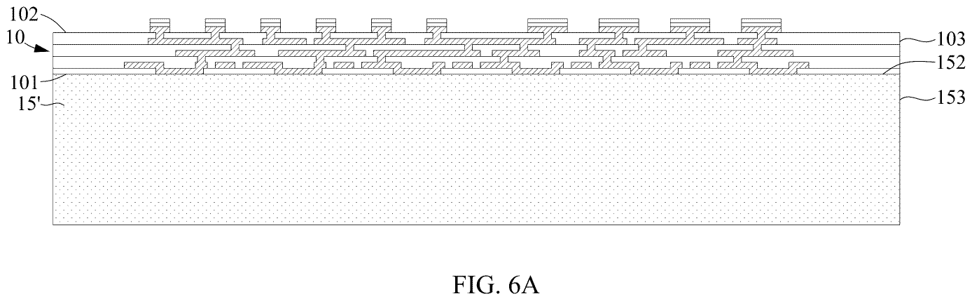

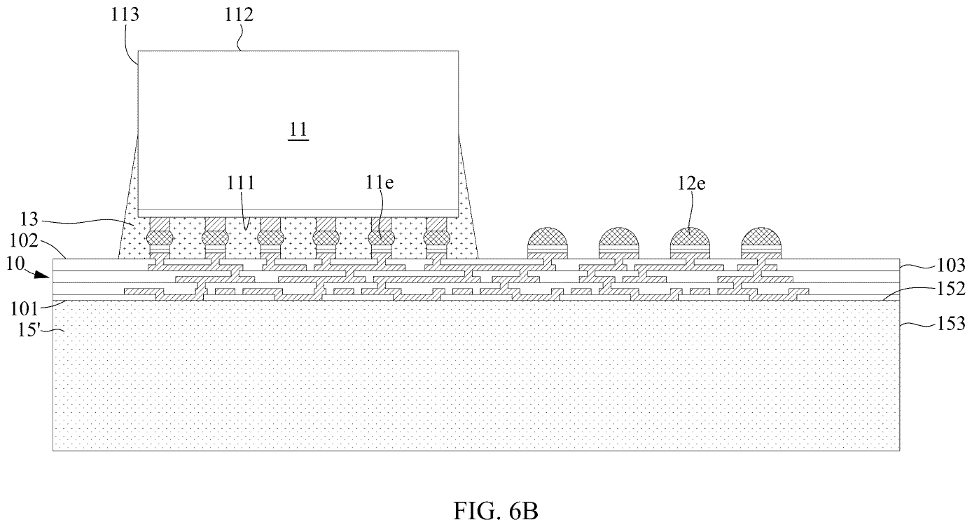

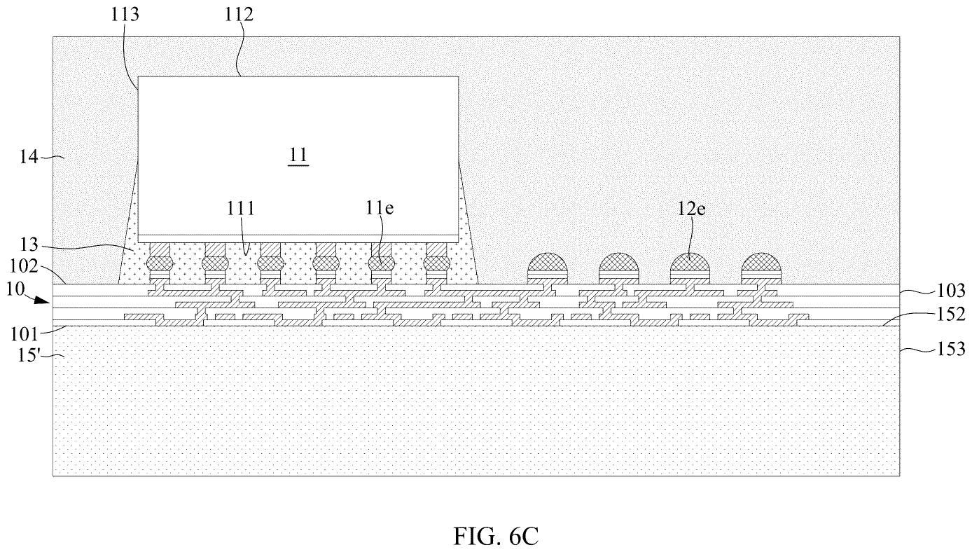

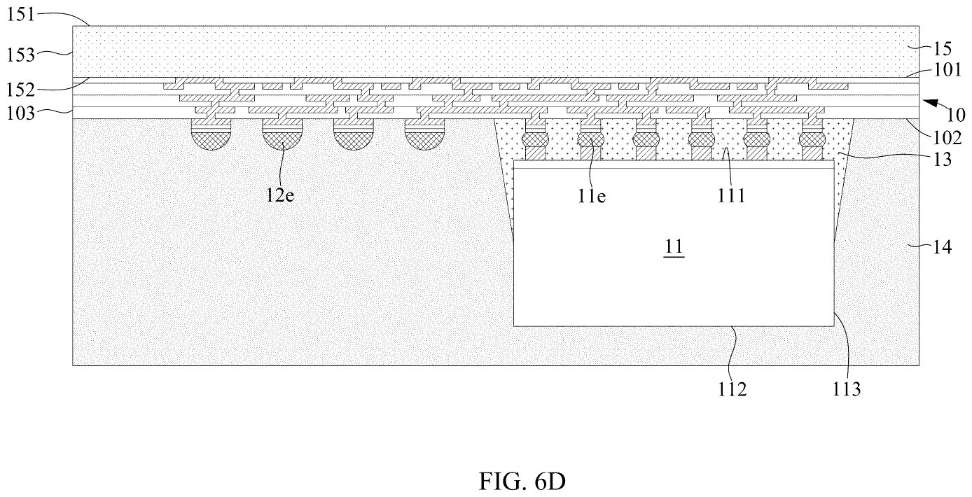

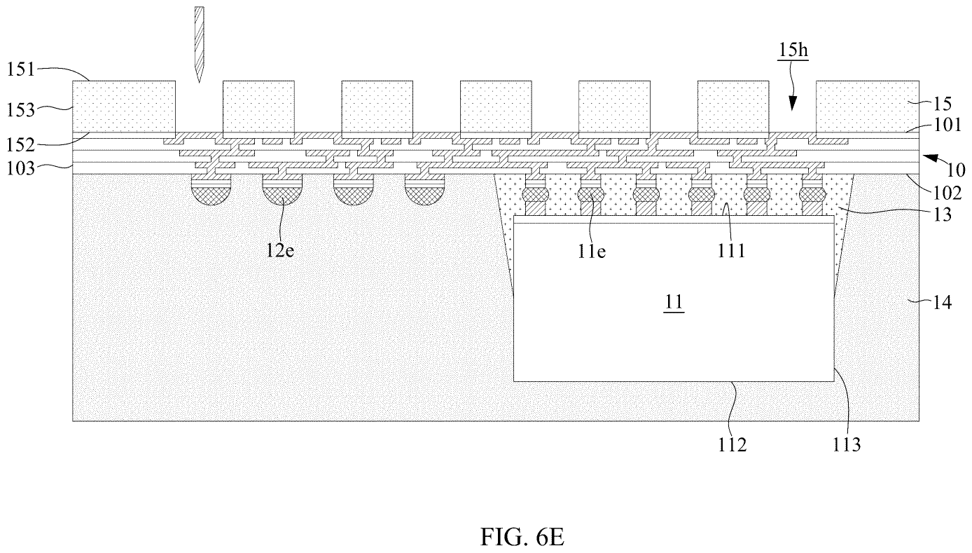

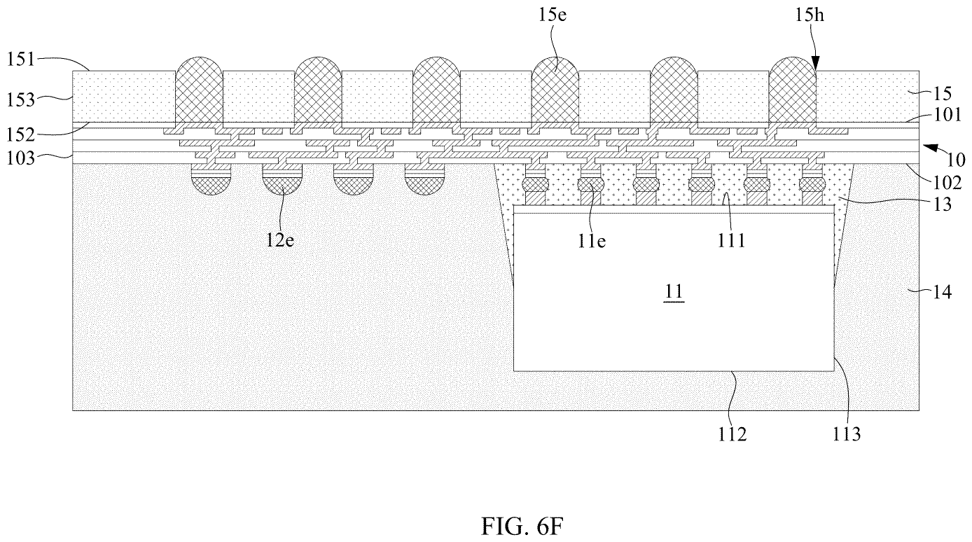

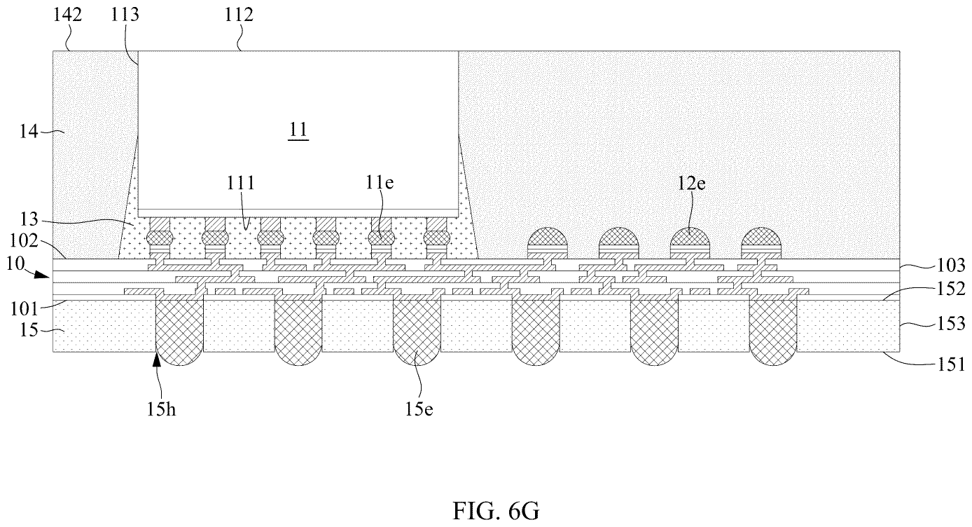

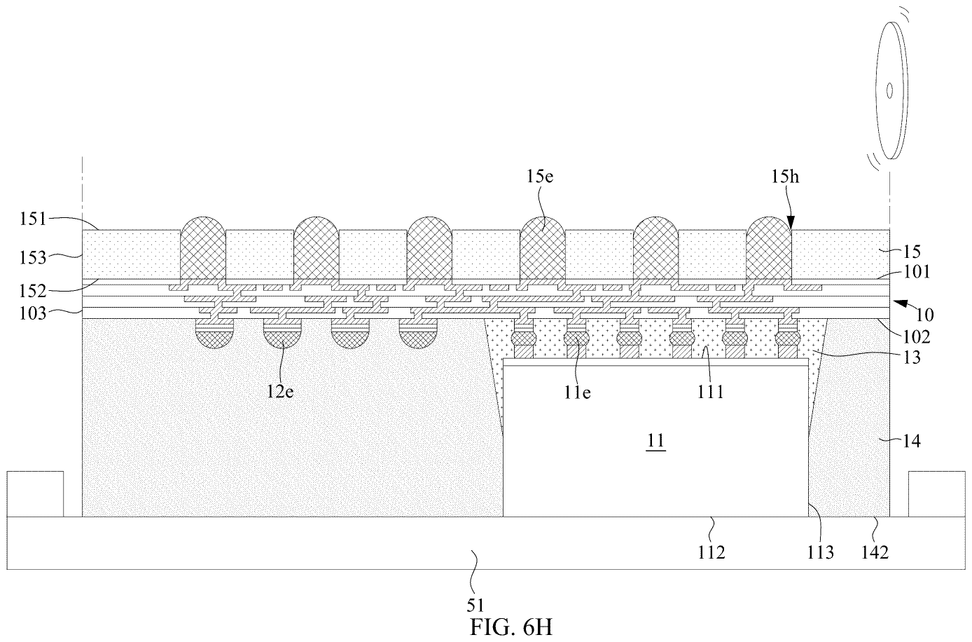

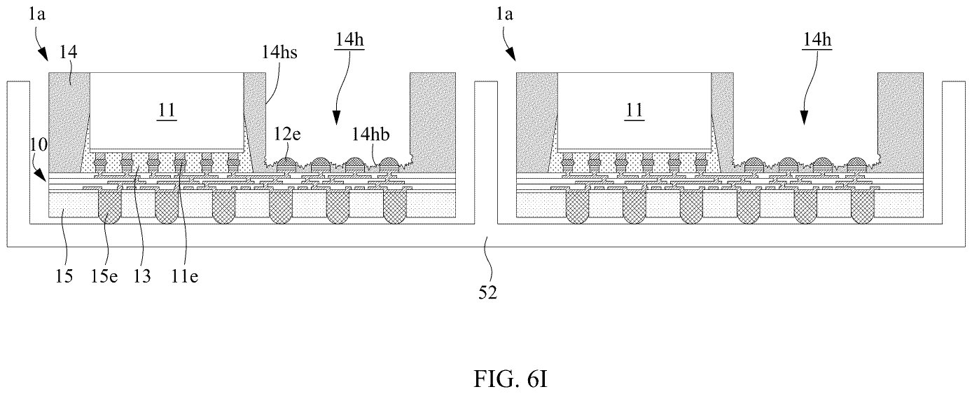

FIGS. 6A, 6B, 6C, 6D, 6E, 6F, 6G, 6H, and 6I are cross-sections of one or more stages of a method of manufacturing an electronic device in accordance with some arrangements of the present disclosure. At least some of these figures have been simplified to better understand the aspects of the present disclosure. In some arrangements, the electronic device 1a may be manufactured through the steps illustrated in FIGS. 6A, 6B, 6C, 6D, 6E, 6F, 6G, 6H, and 6I.

Referring to FIG. 6A, a thicker reinforcement layer 15′may be provided (e.g., manufactured or obtained). The carrier 10 may be formed over the thicker reinforcement layer 15′.

Referring to FIG. 6B, the electronic component 11 may be disposed over the carrier 10. The underfill 13 may be disposed over the carrier 10.

Referring to FIG. 6C, the encapsulant 14 may be disposed over the carrier 10 to cover the electronic component 11 and the underfill 13.

Referring to FIG. 6D, a planarization or grinding operation may be performed to remove a portion of the thicker reinforcement layer 15′, thereby forming the temporary carrier 50. The reinforcement layer 15 may be thinner than the thicker reinforcement layer 15′. The surface 151 of the reinforcement layer 15 may then be exposed.

Referring to FIG. 6E, one or more holes 15h may be formed in the reinforcement layer 15.

Referring to FIG. 6F, the electrical contact 15e may be formed in the holes 15h.

Referring to FIG. 6G, a planarization operation or a grinding operation may be performed to remove a portion of the encapsulant 14 to expose the surface 112 of the electronic component 11.

Referring to FIG. 6H, the structure obtained from the operation of FIG. 5G may be disposed over a dicing tape 51. A singulation operation may be performed.

Referring to FIG. 6I, the individual units obtained from the operation of FIG. 6H may be disposed or sorted over a board 52. The opening 14h may be formed.

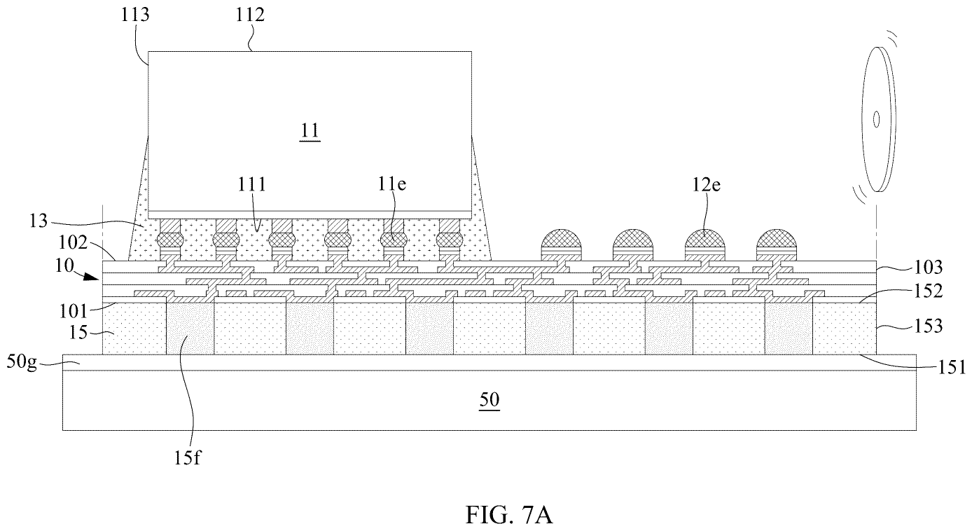

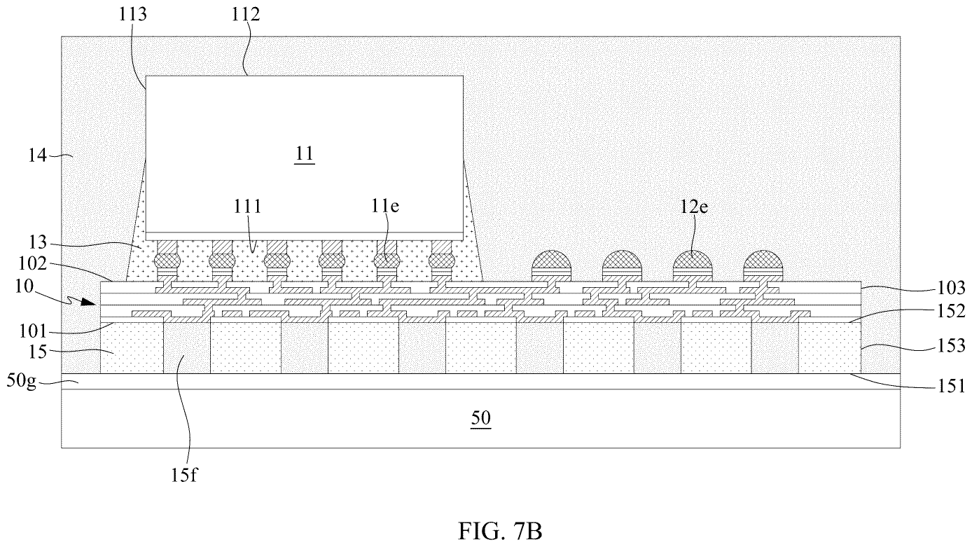

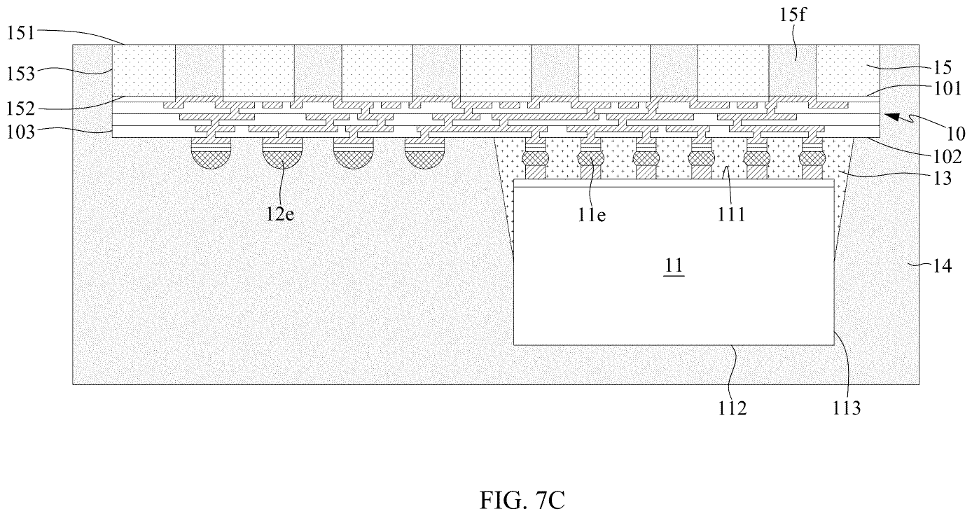

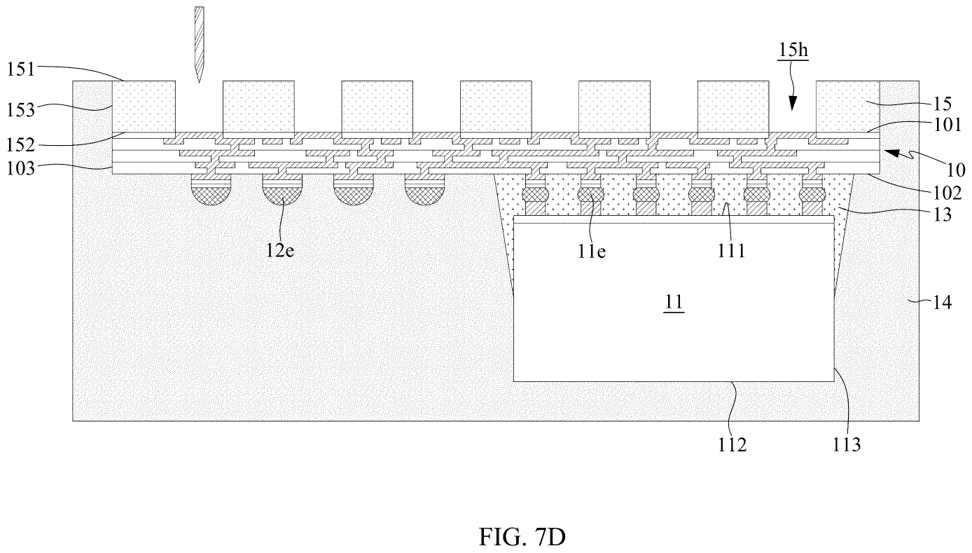

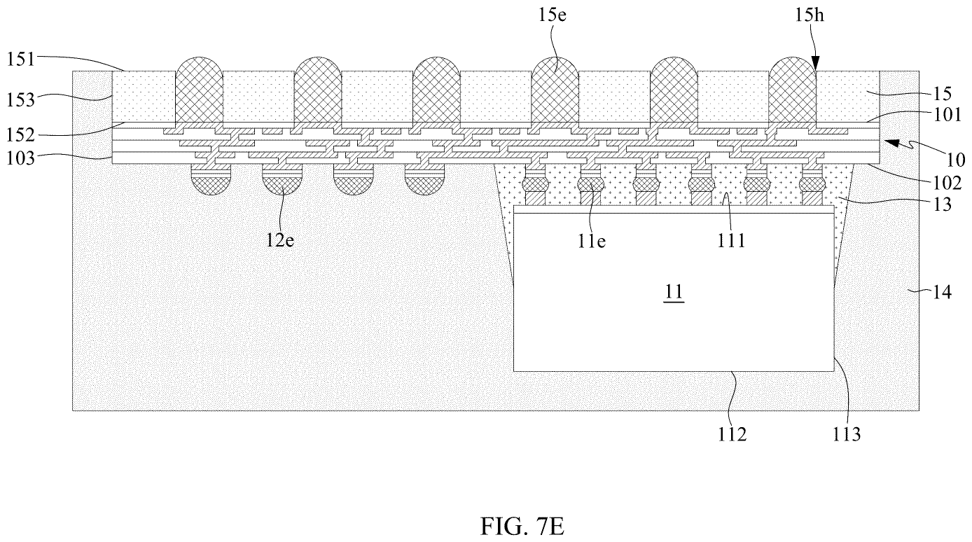

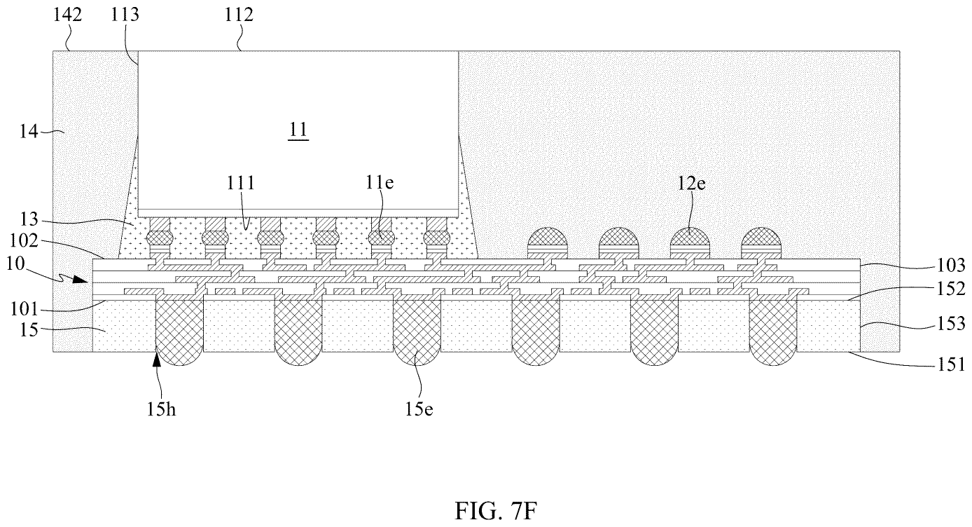

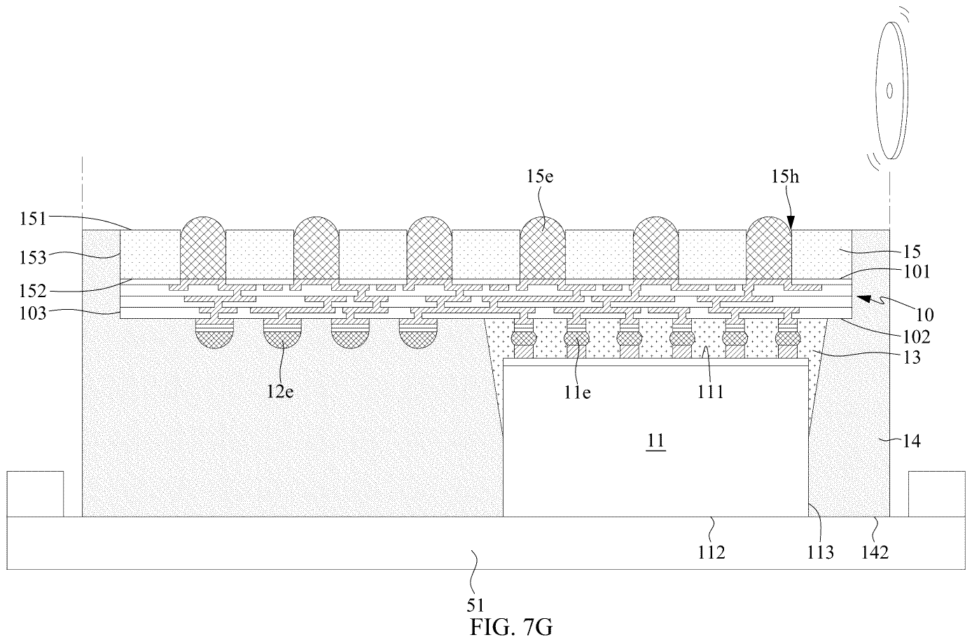

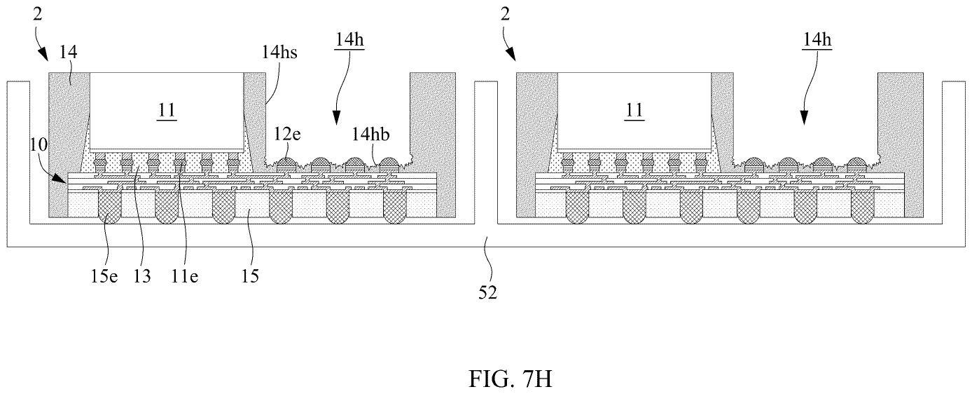

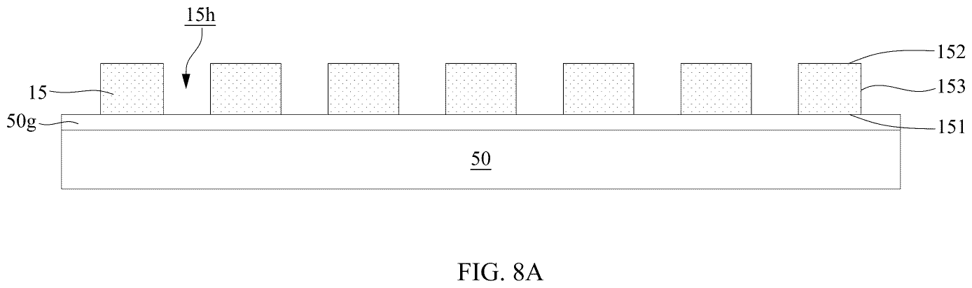

FIGS. 7A, 7B, 7C, 7D, 7E, 7F, 7G, and 7H are cross-sections of one or more stages of a method of manufacturing an electronic device in accordance with some arrangements of the present disclosure. At least some of these figures have been simplified to better understand the aspects of the present disclosure. In some arrangements, the electronic device 2 may be manufactured through the steps illustrated in FIGS. 7A, 7B, 7C, 7D, 7E, 7F, 7G, and 7H.

Referring to FIG. 7A, which may be subsequent to the operations in FIG. 5A and FIG. 5B, a singulation operation may be performed. The electronic device assembly may be singulated or separated into a plurality of strips in a singulation operation. In some arrangements, the singulation operation may be applied using a saw blade or laser cutting tool.

Referring to FIG. 7B, the encapsulant 14 may be disposed over the carrier 10 to cover the electronic component 11 and the underfill 13. The encapsulant 14 may cover the surface 153 of the reinforcement layer 15 and the surface 103 of the carrier 10.

Referring to FIG. 7C, the temporary carrier 50 and the adhesive layer 50g may be removed, and the surface 151 of the reinforcement layer 15 may be exposed.

Referring to FIG. 7D, one or more holes 15h may be formed in the reinforcement layer 15.

Referring to FIG. 7E, the electrical contact 15e may be formed in the holes 15h.

Referring to FIG. 7F, a planarization operation or a grinding operation may be performed to remove a portion of the encapsulant 14 to expose the surface 112 of the electronic component 11.

Referring to FIG. 7G, the structure obtained from the operation of FIG. 7F may be disposed over a dicing tape 51. A singulation operation may be performed. The strips may be singulated or separated into a plurality of individual units in a singulation operation.

Referring to FIG. 7H, the individual units obtained from the operation of FIG. 7G may be disposed or sorted over a board 52. The opening 14h may be formed.

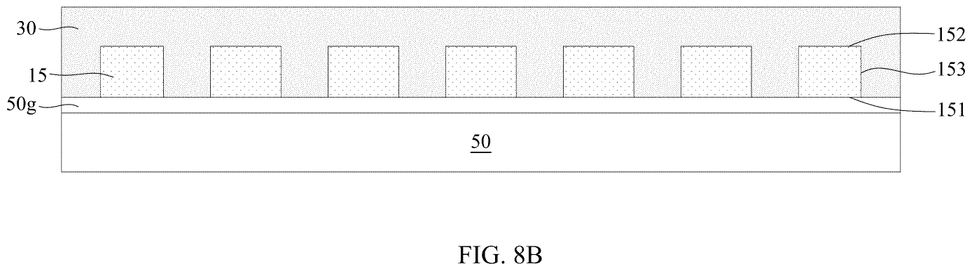

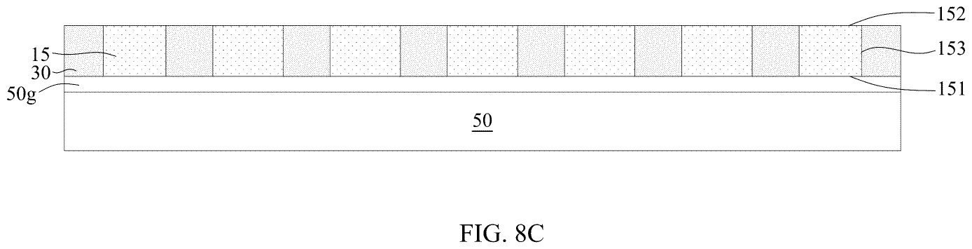

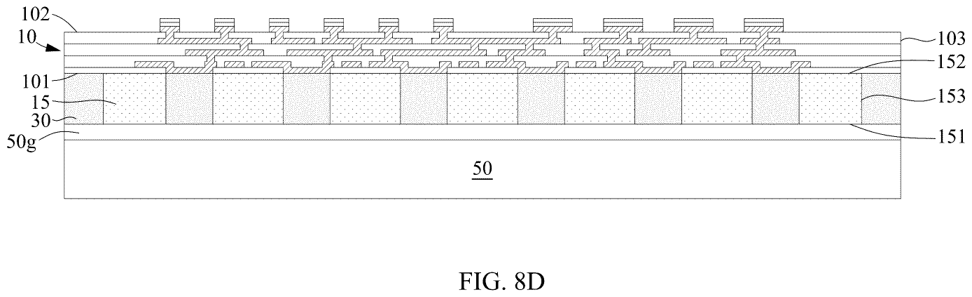

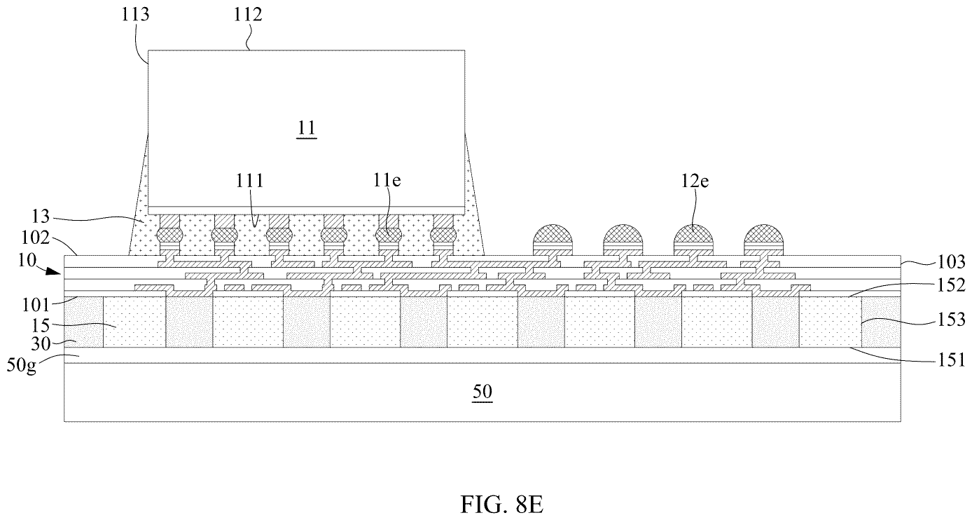

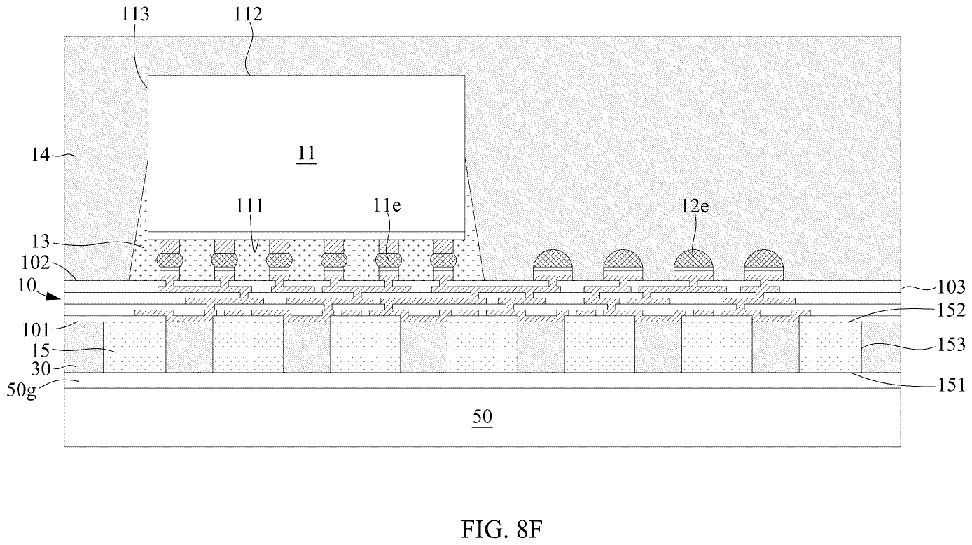

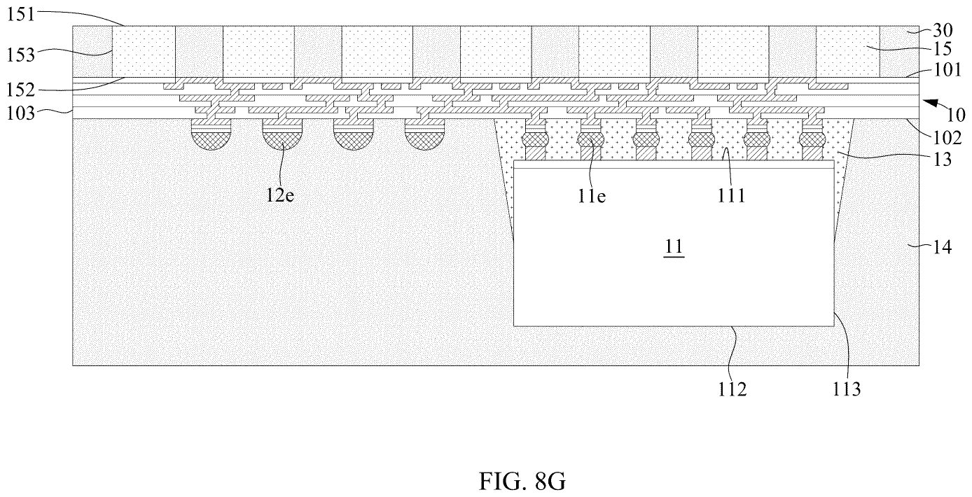

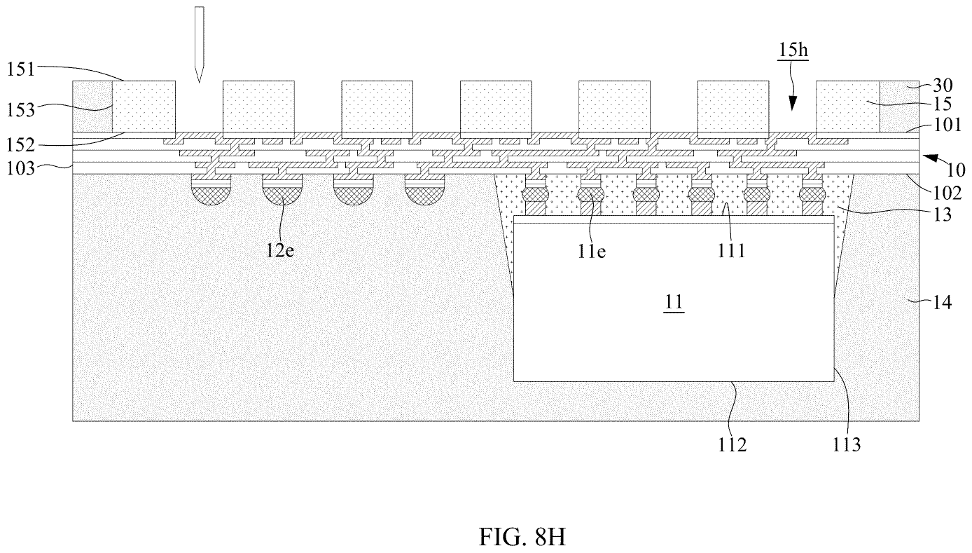

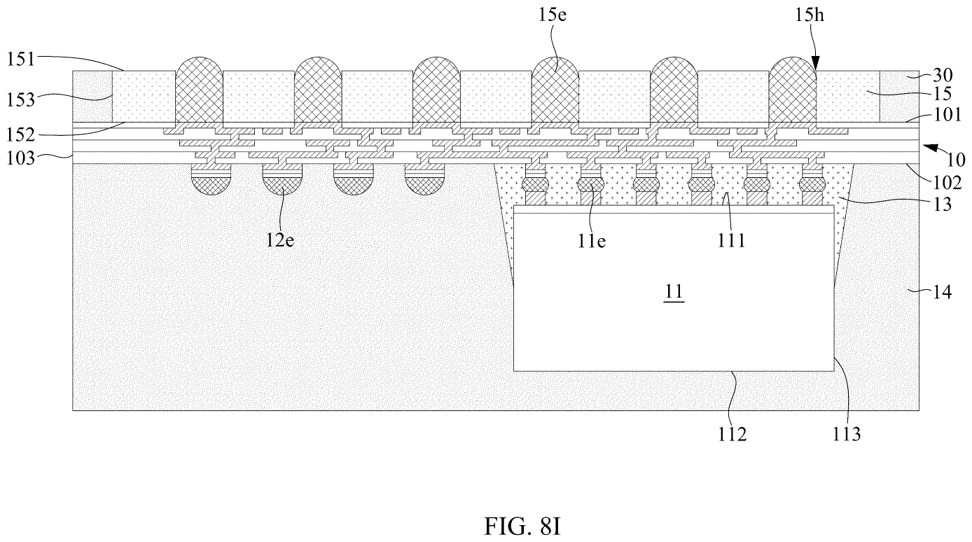

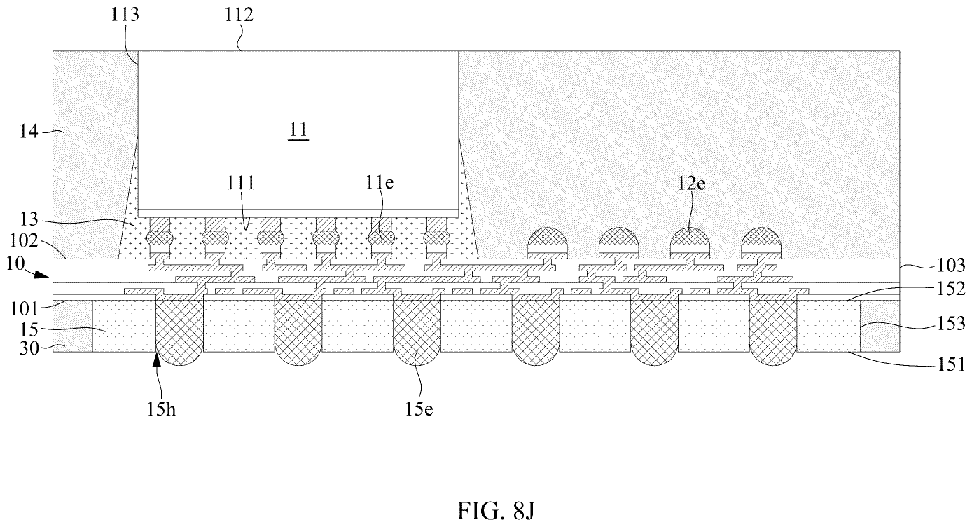

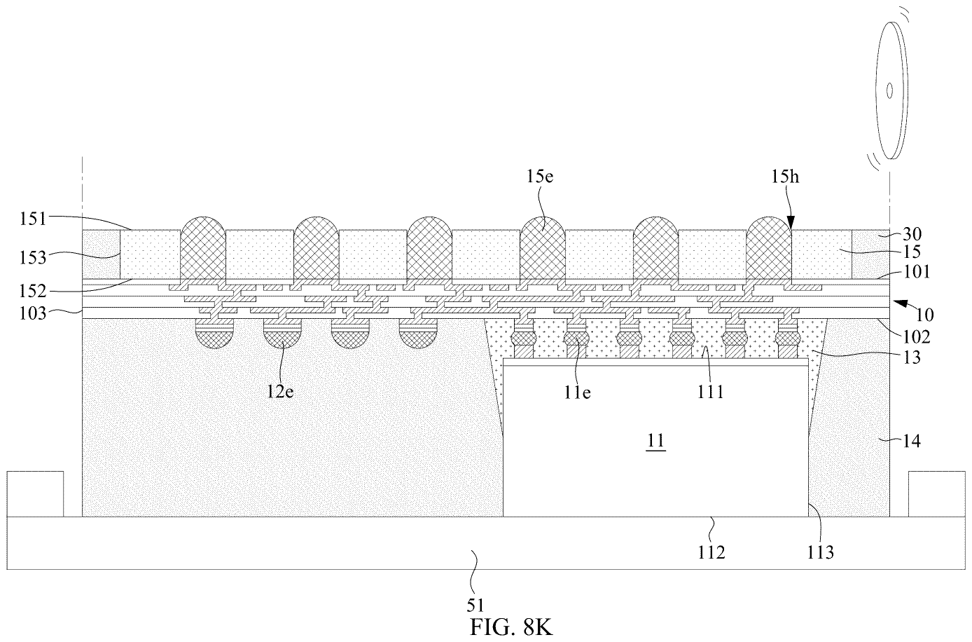

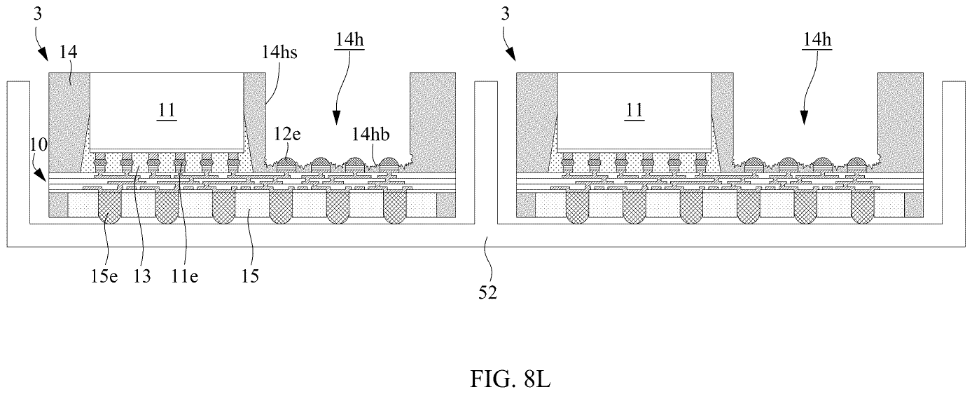

FIGS. 8A, 8B, 8C, 8D, 8E, 8F, 8G, 8H, 8I, 8J, 8K, and 8L are cross-sections of one or more stages of a method of manufacturing an electronic device in accordance with some arrangements of the present disclosure. At least some of these figures have been simplified to better understand the aspects of the present disclosure. In some arrangements, the electronic device 3 may be manufactured through the steps illustrated in FIGS. 8A, 8B, 8C, 8D, 8E, 8F, 8G, 8H, 8I, 8J, 8K, and 8L.

Referring to FIG. 8A, a temporary carrier 50 may be provided (e.g., manufactured or obtained). The reinforcement layer 15 may be formed over the temporary carrier 50. The reinforcement layer 15 may be attached to the temporary carrier 50 through an adhesive layer 50g. The reinforcement layer 15 may include one or more holes 15h. One or more holes 15h may be preformed in the reinforcement layer 15 before the reinforcement layer 15 is attached to the temporary carrier 50.

Referring to FIG. 8B, a layer of the encapsulant 30 may be disposed over the reinforcement layer 15 to fill the holes 15h. In some arrangements, the encapsulant 30 may be formed by a molding technique, such as transfer molding, injection molding, or compression molding.

Referring to FIG. 8C, a planarization operation or a grinding operation may be performed to remove a portion of the encapsulant 30 to expose the surface 152 of the reinforcement layer 15.

Referring to FIG. 8D, the carrier 10 may be formed over the reinforcement layer 15.

Referring to FIG. 8E, the electronic component 11 may be disposed over the carrier 10. The underfill 13 may be disposed over the carrier 10.

Referring to FIG. 8F, the encapsulant 14 may be disposed over the carrier 10 to cover the electronic component 11 and the underfill 13.

Referring to FIG. 8G, the temporary carrier 50 and the adhesive layer 50g may be removed, and the surface 151 of the reinforcement layer 15 may be exposed.

Referring to FIG. 8H, a portion of the encapsulant 30 may be removed, and one or more holes 15h may be formed in the reinforcement layer 15. The encapsulant 30 on the periphery may remain.

Referring to FIG. 8I, the electrical contact 15e may be formed in the holes 15h.

Referring to FIG. 8J, a planarization operation or a grinding operation may be performed to remove a portion of the encapsulant 14 to expose the surface 112 of the electronic component 11.

Referring to FIG. 8K, the structure obtained from the operation of FIG. 8J may be disposed over a dicing tape 51. A singulation operation may be performed.

Referring to FIG. 8L, the individual units obtained from the operation of FIG. 8K may be disposed or sorted over a board 52. The opening 14h may be formed.

FIGS. 9 and 10 illustrate top views of a wafer WF and panel PF according to some embodiments of the present disclosure.

As shown in FIG. 9, the wafer WF may include a semiconductor wafer, a glass wafer, or other suitable wafers. The wafer WF may have a circular profile or the like. The wafer WF may include a plurality of units WD. Each of the units WD may include a die, a package, a module, a component, or the like. The units WD may be separated from each other by scribe lines WL. The units WD may be separated from each other by a singulation technique. The wafer WF may include a unit WD-1 at a central region and a unit WD-2 at a peripheral region. As shown in FIG. 10, the panel PF may include a semiconductor panel, a glass panel, or other suitable panels. The panel PF may have a rectangular profile or the like. The panel PF may include a plurality of units PD. Each of the units PD may include a die, a package, a module, a component, or the like. The units PD may be separated from each other by scribe lines PL. The units PD may be separated from each other by a singulation technique. The panel PF may include a unit PD-1 at a central region and a unit PD-2 at a corner (or peripheral region). As shown in FIG. 9, different columns of the wafer WF may include different quantities of the units WD. Different rows of the wafer WF may include different quantities of the units WD. As shown in FIG. 10, different columns of the panel PF may include the same number of the units PD. Different rows of the panel PF may include the same number of the units PD. As shown in FIG. 9, the scribe line WL is not parallel to the edge of the wafer WF. As shown in FIG. 10, the scribe line PL may be substantially parallel to the edge of the panel PF.

A layer (e.g., dielectric layer or conductive layer) may be formed on the wafer WF by spin-on coating, sputtering, plating or other techniques. A layer (e.g., dielectric layer or conductive layer) may be formed on the panel PF by spray coating, doctor blade coating, roll-to-roll coating, sputtering, plating, or other techniques. Since the panel PF has a rectangular profile, the circuit pattern on the panel PF may exhibit greater thickness at the corners (or peripheral region) and reduced thickness in the central region, a variation attributed to corona discharge. For example, the circuit layer of the unit PD-2 has a greater thickness, and the circuit layer of the unit PD-1 has a smaller thickness. In comparison, the thickness of the circuit layers of the wafer WF may vary due to loading effects or other factors, resulting in thickness differences between units in different locations. To improve thickness uniformity, the panel PF may have dummy patterns. The density of these dummy patterns, which serve no electrical function, is higher at the corners (or peripheral region) than in the central region. For example, the density of the dummy patterns abutting or within the unit PD-2 may be greater than the density of the dummy patterns abutting or within the unit PD-1. The units WD on the wafer WF may be arranged with a higher density in the central region and a lower density in the peripheral region. The units PD on the panel PF may be arranged with substantially the same density in the central region and in the corners (or peripheral region).

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a redistribution layer (RDL) having a first surface and a second surface opposite the first surface;
an electronic component disposed over the first surface of the RDL; and
a reinforcement layer disposed over the second surface of the RDL.

2. The electronic device of claim 1, wherein the RDL includes a first circuit portion and a second circuit portion having different circuit densities.

3. The electronic device of claim 1, further comprising:
a plurality of electrical contacts disposed over the second surface of the RDL, and wherein the reinforcement layer includes a plurality of holes configured to accommodate the plurality of electrical contacts.

4. The electronic device of claim 1, wherein the reinforcement layer includes an interconnection structure penetrating through the reinforcement layer.

5. The electronic device of claim 1, further comprising:
a plurality of electrical contacts disposed over the first surface of the RDL, a portion of the first surface of the RDL adjacent to the plurality of electrical contacts is jagged.

6. The electronic device of claim 1, wherein a lateral surface of the reinforcement layer is substantially aligned with a lateral surface of the RDL.

7. The electronic device of claim 6, further comprising:
an encapsulant disposed over the RDL and covering the lateral surface of the reinforcement layer.

8. The electronic device of claim 1, wherein a lateral surface of the reinforcement layer is misaligned with a lateral surface of the RDL.

9. An electronic device, comprising:
a redistribution layer (RDL) having a first surface and a second surface opposite the first surface;
a first encapsulant disposed over the first surface of the RDL;
a reinforcement structure disposed over the second surface of the RDL; and
a second encapsulant disposed over the second surface of the RDL and adjacent to the reinforcement structure.

10. The electronic device of claim 9, further comprising:
a first group of electrical contacts and a second group of electrical contacts disposed over the first surface of the RDL, wherein a line spacing of the first group of electrical contacts is narrower than a line spacing of the second group of electrical contacts.

11. The electronic device of claim 10, wherein the first encapsulant defines an opening over the second group of electrical contacts.

12. The electronic device of claim 11, wherein the opening is configured to accommodate a memory package.

13. The electronic device of claim 11, wherein a bottom of the opening is higher than the first surface of the RDL.

14. The electronic device of claim 13, wherein the bottom of the opening has a non-planar surface.

15. The electronic device of claim 11, wherein the opening is exposed to an external environment through a side of the encapsulant.

16. The electronic device of claim 15, wherein the side of the encapsulant defines a plurality of sub-openings smaller than the opening.

17. A method for manufacturing an electronic device, comprising:
forming a reinforcement layer;
forming an RDL over the reinforcement layer;
forming an encapsulant over the RDL; and
forming an opening in the encapsulant.

18. The method of claim 17, further comprising:
performing an electrical test on the RDL; and
disposing a memory package in the opening.

19. The method of claim 17, wherein the reinforcement layer includes a filling material, and the method further comprises:
removing the filling material to form a plurality of holes in the reinforcement layer.

20. The method of claim 17, further comprising:
thinning the reinforcement layer; and
forming a plurality of holes in the reinforcement layer.
